(19) United States
(12) Patent Application Publication
(10) Pub. No.: US 2025/0338480 A1
(43) Pub. Date: Oct. 30, 2025

(54) MEMORY DEVICES AND MANUFACTURING METHODS THEREOF

(71) Applicant: Yangtze Memory Technologies Co., Ltd., Wuhan (CN)

(72) Inventors: Zongliang HUO, Wuhan (CN); Wei XU, Wuhan (CN)

(21) Appl. No.: 19/182,694

(22) Filed: Apr. 18, 2025

(30) Foreign Application Priority Data
Apr. 29, 2024 (CN) 202410547214.4

(51) Int. Cl. H10B 12/00

(52) U.S. Cl. CPC H10B 12/315; H10B 12/05

(57) ABSTRACT

Implementations of the present disclosure provide a memory device and a manufacturing method thereof. The memory device includes: a semiconductor structure, the semiconductor structure comprising: a semiconductor pillar extending along a first direction; a gate structure located on at least one side of the semiconductor pillar; and a first doped area located at two opposite ends of the semiconductor pillar along the first direction, wherein along a direction in which the gate structure points to the semiconductor pillar, a doping concentration on a first side of the first doped area close to the gate structure is greater than a doping concentration on a second side of the first doped area away from the gate structure.

### CROSS-REFERENCE TO RELATED APPLICATIONS

The present application claims the benefit of priority to Chinese Application No. 202410547214.4, filed on Apr. 29, 2024, which is hereby incorporated by reference in its entirety.

### TECHNICAL FIELD

The present disclosure relates to the technical field of semiconductors, and specifically, to memory devices and manufacturing methods thereof.

BACKGROUND

A memory device, for example, a dynamic random access memory (DRAM) is one of the most important access components in an electronic system. One transistor and one capacitor usually form a 1T1C structure as one memory cell. With such a 1T1C structure, a dynamic random access memory has a high integration level and a low cost, and has an irreplaceable position in computer access devices. With the rapid development of semiconductor technologies, dynamic random access memories develop rapidly in the direction of high density and high quality.

### SUMMARY

In view of this, Implementations of the present disclosure provide a memory device and a manufacturing method thereof.

According to a first aspect of Implementations of the present disclosure, a memory device is provided. The memory device may include a semiconductor structure. The semiconductor structure may include a semiconductor pillar, a gate structure and a first doped area. The semiconductor pillar may extend along a first direction. The gate structure may be located on at least one side of the semiconductor pillar. The first doped area may be located at two opposite ends of the semiconductor pillar along the first direction. Along a direction in which the gate structure points to the semiconductor pillar, a doping concentration on a first side of the first doped area close to the gate structure may be greater than a doping concentration on a second side of the first doped area away from the gate structure.

In an implementation, a doping concentration of the first doped area may decrease along the direction in which the gate structure points to the semiconductor pillar.

In an implementation, the first doped area may include a first portion located at a first end of the semiconductor pillar and a second portion located at a second end of the semiconductor pillar. The first end and the second end are two opposite ends of the semiconductor pillar along the first direction. A spacing between an end surface of the gate structure close to the first portion and an end surface of the first portion close to the gate structure along the first direction and a spacing between an end surface of the gate structure close to the second portion and an end surface of the second portion close to the gate structure are both less than or equal to a first preset threshold.

In an implementation, a range of the first preset threshold is 5 nm to 10 nm.

In an implementation, the memory device may include a plurality of semiconductor structures. Adjacently disposed semiconductor structures are spaced apart by a dielectric layer. The first doped area may extend a first preset size from a side surface in contact with the dielectric layer along a direction in which the gate structure points to the semiconductor pillar. Along the direction in which the gate structure points to the semiconductor pillar, the first doped area has the largest doping concentration on the side surface of the first doped area in contact with the dielectric layer.

In an implementation, the semiconductor structure further may include a source and a drain. The source and the drain are respectively located at ends of the first portion and the second portion of the first doped area away from the gate structure along the first direction. The smallest doping concentrations of the source and the drain are greater than the largest doping concentration of the first doped area.

In an implementation, a doping concentration of the source may decrease along a direction in which the first end points to the second end. A doping concentration of the drain may decrease along a direction in which the second end points to the first end.

In an implementation, the semiconductor structure may further include a channel area. The channel area may be a region other than the first doped area between the source and the drain. The smallest doping concentration of the first doped area may be greater than the largest doping concentration of the channel area.

In an implementation, the memory device may include a plurality of semiconductor structures. Adjacently disposed semiconductor structures may be spaced apart by a dielectric layer. A doped ion concentration of the dielectric layer is less than or equal to a second preset threshold.

In an implementation, the plurality of semiconductor structures may include a first semiconductor structure and a second semiconductor structure that are adjacently disposed. At least one of the gate structure of the first semiconductor structure and the gate structure of the second semiconductor structure may be located on one of two sides of a respective semiconductor pillar away from the dielectric layer. The plurality of semiconductor structures may further include a third semiconductor structure. The third semiconductor structure may be located on a side of the first semiconductor structure away from the second semiconductor structure. The memory device may further include a word line isolation structure. The gate structure of the third semiconductor structure and the gate structure of the first semiconductor structure may be spaced apart by the word line isolation structure. A size of the word line isolation structure along the first direction may be greater than a size of the gate structure along the first direction.

In an implementation, the plurality of semiconductor structures may include a first semiconductor structure and a second semiconductor structure that are adjacently disposed. At least one of the gate structure of the first semiconductor structure and the gate structure of the second semiconductor structure may be located on one of two sides of a respective semiconductor pillar away from the dielectric layer. At least one of the first semiconductor structure and the second semiconductor structure further may include a second doped area, wherein the second doped area extends a second preset size from a side surface in contact with the dielectric layer toward the gate structure. A doping type of the second doped area may be different from a doping type of at least one of a source and a drain.

In an implementation, the smallest doping concentrations of the source and the drain may be both greater than the largest doping concentration of the second doped area.

In an implementation, the doping types of the source and the drain may be an N type, and the doping type of the second doped area may be a P type.

According to a second aspect of Implementations of the present disclosure, a memory device is provided. The memory device may include a semiconductor pillar array, a plurality of word lines, a first doped area and a third doped area. The semiconductor pillar array may include a plurality of rows of semiconductor pillars and a plurality of columns of semiconductor pillars. The semiconductor pillar may extend along a first direction. One of the plurality of word lines may cover a part of a sidewall of one row of semiconductor pillars. The first doped area may be located at two opposite ends of the semiconductor pillar in a first region along the first direction. The first region may be a region where both a word line and a bit line extend through. Along a direction in which the word line points to the semiconductor pillar, a doping concentration on a first side of the first doped area close to the word line may be greater than a doping concentration on a second side of the first doped area away from the word line. The third doped area may be located at two opposite ends of the semiconductor pillar in a second region along the first direction. The second region may be located between the first region and a third region. The third region may be configured for arranging a word line contact structure. A doping concentration on a first side of the third doped area close to the word line may be equal to a doping concentration on a second side of the third doped area away from the word line.

In an implementation, a spacing between an end surface of the word line close to the first doped area and an end surface of the first doped area close to the word line along the first direction may be less than or equal to a first preset threshold. A spacing between an end surface of the word line close to the third doped area and an end surface of the third doped area close to the word line in the first direction may be greater than the first preset threshold.

In an implementation, a range of the first preset threshold is 5 nm to 10 nm.

In an implementation, a size of the first doped area along a preset direction may be less than or equal to a size of the semiconductor pillar along the preset direction. The preset direction may be the same as an arrangement direction of semiconductor pillars in one column of semiconductor pillars. A size of the third doped area along the preset direction may be equal to the size of the semiconductor pillar along the preset direction.

In an implementation, the memory device may further include a source and a drain. At least one of the first doped area and the third doped area may include a first portion located at a first end of the semiconductor pillar and a second portion located at a second end of the semiconductor pillar. The first end and the second end are two opposite ends of the semiconductor pillar along the first direction. The source and the drain may be respectively located at ends of the first portion and the second portion of the first doped area/the third doped area away from the word line along the first direction. The smallest doping concentrations of the source and the drain may be greater than the largest doping concentration of the first doped area. The smallest doping concentrations of the source and the drain may be greater than the largest doping concentration of the third doped area.

According to a third aspect of Implementations of the present disclosure, a manufacturing method of a memory device is provided. The manufacturing method may include providing a semiconductor layer. The manufacturing method may include forming a semiconductor structure in the semiconductor layer. The semiconductor structure may include a semiconductor pillar, a gate structure, and a first doped area. Forming the semiconductor structure may include forming the semiconductor pillar extending along a first direction. Forming the semiconductor structure may include forming the gate structure on at least one side of the semiconductor pillar. Forming the semiconductor structure may include forming the first doped area at two opposite ends of the semiconductor pillar along the first direction. Along a direction in which the gate structure points to the semiconductor pillar, a doping concentration on a first side of the first doped area close to the gate structure may be greater than a doping concentration on a second side of the first doped area away from the gate structure.

In an implementation, forming the gate structure and the first doped area may include forming a first initial gate covering at least one side of the semiconductor pillar. Forming the gate structure and the first doped area may include removing a part of the first initial gate along the first direction from a first surface and a second surface of the semiconductor layer, respectively, to form the gate structure and expose a part of the semiconductor pillar, wherein the first surface and the second surface are two opposite surfaces of the semiconductor layer along the first direction. Forming the gate structure and the first doped area may include forming the first doped area from surfaces of exposed parts of the semiconductor pillar, respectively, in a region extending a first preset size along a direction perpendicular to the first direction.

In an implementation, forming the gate structure and the first doped area may include forming a sacrificial layer at a bottom of at least one side of the semiconductor pillar. Forming the gate structure and the first doped area may include forming a second initial gate covering a respective side of the semiconductor pillar on the sacrificial layer. Forming the gate structure and the first doped area may include removing a top portion of the second initial gate and the sacrificial layer, to form the gate structure and expose a top and a bottom of a respective side surface of the semiconductor pillar. Forming the gate structure and the first doped area may include forming the first doped area from surfaces of exposed parts of the semiconductor pillar, respectively, in a region extending a first preset size along a direction perpendicular to the first direction.

In an implementation, forming the first doped area may include forming first portions and second portions of the first doped areas from surfaces of exposed parts of the semiconductor pillar, respectively, in a region extending the first preset size along a direction perpendicular to the first direction by a molecular layer deposition process or a rapid vapor deposition process.

In an implementation, forming a first portion of the first doped area may include removing a part of the first initial gate from the first surface of the semiconductor layer along the first direction to form a third initial gate, so as to expose a part of the semiconductor pillar. Forming a first portion of the first doped area may include forming a first initial portion of the first doped area from a surface of the exposed part of the semiconductor pillar in a region extending the first preset size along a direction perpendicular to the first direction. Forming a first portion of the first doped area may include doping a part of the first initial portion away from the third initial gate from the first surface of the semiconductor layer along the first direction by an ion implantation process, wherein the doped portion may form a source, and the remaining first initial portion that is not doped by an ion implantation process forms the first portion of the first doped area.

In an implementation, forming a second portion of the first doped area may include after forming the source and the first portion, removing a part of the third initial gate from the second surface of the semiconductor layer along the first direction to form the gate structure, so as to expose a part of the semiconductor pillar. Forming a second portion of the first doped area may include forming a second initial portion of the first doped area from a surface of the exposed part of the semiconductor pillar in a region extending the first preset size along a direction perpendicular to the first direction. Forming a second portion of the first doped area may include doping a partial region of the second initial portion away from the gate structure from the second surface of the semiconductor layer along the first direction by an ion implantation process, wherein the doped partial region forms a drain, and the remaining second initial portion that is not doped by using an ion implantation process forms the second portion of the first doped area.

In an implementation, forming a first portion and a second portion of the first doped area may include forming a drain at the bottom of at least one side of the semiconductor pillar by a diffusion process. Forming a first portion and a second portion of the first doped area may include forming first initial portions and the second portions of the first doped areas from surfaces of exposed parts of the semiconductor pillar at a top and a bottom of a respective side surface, respectively, in a region extending the first preset size along a direction perpendicular to the first direction. Forming a first portion and a second portion of the first doped area may include doping a partial region of the first initial portion away from the gate structure from a top portion of the semiconductor layer along the first direction by an ion implantation process, wherein the doped partial region forms a source, and the remaining first initial portion that is not doped by an ion implantation process forms the first portion of the first doped area.

Implementations of the present disclosure provide a memory device and a manufacturing method thereof. The manufacturing method may include providing a semiconductor layer. The manufacturing method may include forming a semiconductor structure in the semiconductor layer. The semiconductor structure may include a semiconductor pillar, a gate structure, and a first doped area. Forming the semiconductor structure may include forming the semiconductor pillar extending along a first direction. Forming the semiconductor structure may include forming the gate structure on at least one side of the semiconductor pillar. Forming the semiconductor structure may include forming the first doped area at two opposite ends of the semiconductor pillar along the first direction. Along a direction in which the gate structure points to the semiconductor pillar, a doping concentration on a first side of the first doped area close to the gate structure may be greater than a doping concentration on a second side of the first doped area away from the gate structure. In Implementations of the present disclosure, during the formation of the gate structure, a part of the surface of the semiconductor pillar is exposed by removing an initial gate (a first/second initial gate), to provide a positioning reference for a formation position of the first doped area, thereby improving the alignment precision of the first doped area and the gate structure, reducing the alignment difficulty of the first doped area and the gate structure, and improving the reliability of the memory device. In another aspect, the doping concentration on the first side of the first doped area close to the gate structure is greater than the doping concentration on the second side of the first doped area away from the gate structure, which helps to reduce an electric field in a horizontal direction (X direction), and improves the performance and reliability of the memory device.

### BRIEF DESCRIPTION OF THE DRAWINGS

In the drawings (which are not necessarily drawn to scale), similar reference numerals may denote the similar components in different figures. Like reference numerals having different letter suffixes may represent different examples of like components. The drawings generally illustrate the various Implementations discussed herein by way of examples rather than limitation.

FIG. 1 is a schematic diagram of a circuit connection of a transistor according to an implementation of the present disclosure.

FIG. 2A is a schematic structural diagram of a dynamic random access memory according to an implementation of the present disclosure.

FIG. 2B is an enlarged schematic diagram of a region A in FIG. 2A.

FIG. 2C is a partial schematic structural diagram of a dynamic random access memory according to an implementation of the present disclosure.

FIG. 3 is a schematic flow diagram of a manufacturing method of a memory device according to an implementation of the present disclosure.

FIG. 4 is a schematic flow diagram of a formation method of a semiconductor structure according to an implementation of the present disclosure.

FIGS. 5A to 5C are schematic cross-sectional views of a process of forming a semiconductor pillar according to an implementation of the present disclosure.

FIGS. 5D to 5J are schematic cross-sectional views of a process of forming a gate structure and a first doped area according to an implementation of the present disclosure.

FIGS. 6A and 6B are schematic cross-sectional views of a process of forming a memory device according to an implementation of the present disclosure.

FIGS. 7A to 7D are schematic cross-sectional views of another process of forming a memory device according to an implementation of the present disclosure.

FIG. 8A is a schematic structural diagram of a memory device according to an implementation of the present disclosure.

FIG. 8B is an enlarged schematic diagram of a region C in FIG. 8A.

FIG. 9 is a schematic structural diagram of still another memory device according to an implementation of the present disclosure.

### DETAILED DESCRIPTION

Example implementations disclosed by the present disclosure will be described below in more details with reference to the drawings. Although the example implementations of the present disclosure are shown in the drawings. The present disclosure may be implemented in various forms and should not be limited by the specific implementations set forth herein. Rather, these implementations are provided for a more thorough understanding of the present disclosure, and to fully convey a scope disclosed by the present disclosure to those skilled in the art.

In the following description, numerous specific details are given in order to provide a more thorough understanding of the present disclosure. However, it is apparent to those skilled in the art that the present disclosure may be practiced without one or more of these details. In other examples, in order to avoid confusion with the present disclosure, some technical features well-known in the art are not described. Namely, all the features of the actual examples are not described here, and well-known functions and structures are not described in detail.

In the drawings, the sizes of a layer, a region, and an element and their relative sizes may be exaggerated for clarity. Like reference numerals denote like elements throughout the specification.

It should be understood that, spatially relative terms, such as “beneath”, “below”, “lower”, “under”, “over”, “upper”, and the like, may be used herein for ease of description to describe the relationship between one element or feature and other elements or features as illustrated in the figures. The spatially relative terms are intended to further encompass different orientations of a device in use or operation in addition to the orientation depicted in the figures. For example, if the device in the drawings is turned over, then the elements or the features described as “below” or “under” or “beneath” other elements may be oriented “on” the other elements or features. Therefore, the example terms “below” and “beneath” may include both upper and lower orientations. The device may be otherwise oriented (rotated by 90 degrees or other orientations) and the spatial descriptions used here are interpreted accordingly.

The terms used herein are only intended to describe the specific implementations, and are not used as limitations of the present disclosure. As used herein, unless otherwise indicated expressly in the context, “a”, “an” and “the” in a singular form are also intended to include a plural form. It should also be understood that terms “consist of” and/or “include”, when used in this specification, determine the presence of the described features, integers, steps, operations, elements and/or components, but do not preclude the presence or addition of one or more of other features, integers, steps, operations, elements, components, and/or groups. As used herein, the term “and/or” includes any or all combinations of the listed relevant items.

In order to be capable of understanding the characteristics and the technical contents of the implementations of the present disclosure in more detail, implementations of the examples of the present disclosure are set forth in detail below in conjunction with the drawings, and the appended drawings are only used for reference and illustration, instead of limiting the implementations of the present disclosure.

The memory device to which implementations of the present disclosure relate is at least part of a structure to be used in subsequent processes to form a final device. Here, the final device may include a memory that includes, but is not limited to, a dynamic random access memory. The description is made below only taking a dynamic random access memory as an example. The description below with respect to the dynamic random access memory is only used to illustrate the present disclosure, instead of limiting the scope of the present disclosure.

With the development of a dynamic random access memory technology, the size of a memory cell is increasingly smaller, and its array architecture becomes from 8F² to 6F² and to 4F². In addition, based on the requirements in the dynamic random access memory for ions and leakage current, an architecture of a memory becomes a recess gate array transistor from a planar array transistor, then from the recess gate array transistor to a buried saddle fin array transistor, and then from the buried saddle fin array transistor to a vertical gate transistor.

In a practical application, regardless of the planar transistor, the recess gate array transistor, the buried saddle fin transistor or the vertical gate transistor, the dynamic random access memory is composed of a plurality of memory cell structures each being mainly composed of one transistor and one memory cell (memory capacitor) manipulated by the transistor, i.e., the dynamic random access memory includes 1 transistor (T) and 1 capacitor (C), i.e., a 1T1C architecture, and its major action principle is to represent whether a binary bit is 1 or 0 using an amount of charge stored in the capacitor.

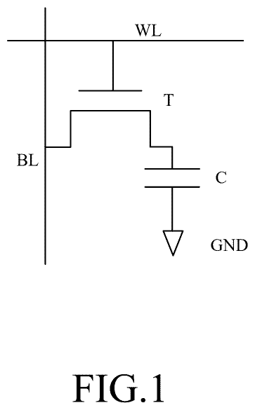

FIG. 1 is a schematic diagram of a circuit connection employing a 1T1C architecture according to an implementation of the present disclosure. As shown in FIG. 1, a drain of a transistor T is electrically connected with a bit line (BL), a source of the transistor T is electrically connected with one of electrode plates of a capacitor C, the other electrode plate of the capacitor C is grounded through a ground terminal (GND), and a gate of the transistor T is connected with a word line (WL). A voltage is applied through the word line WL to control on or off of the transistor T, and the bit line BL is configured to perform a read or write operation on the transistor T when the transistor T is turned on.

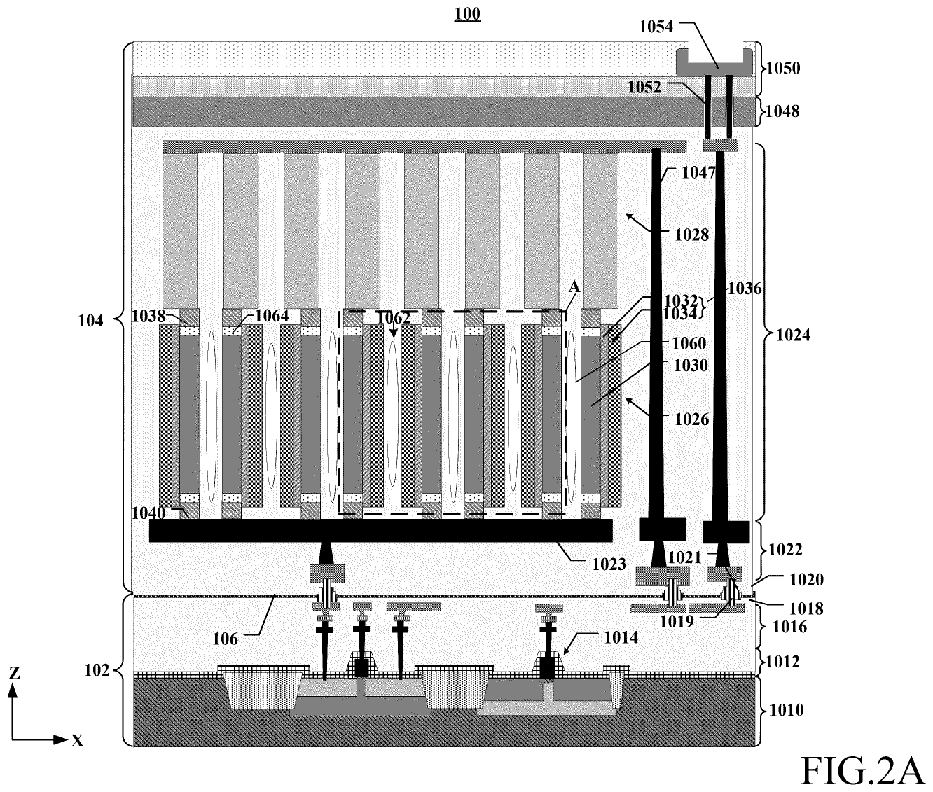

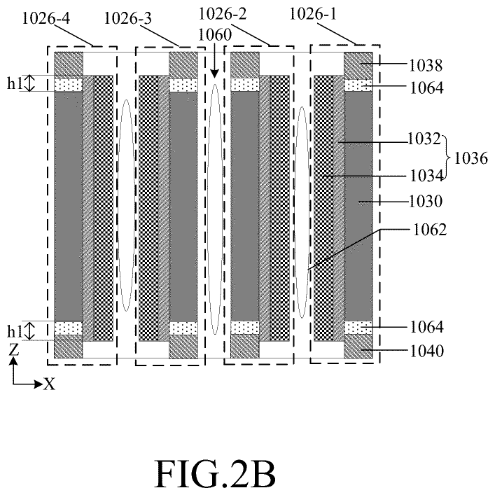

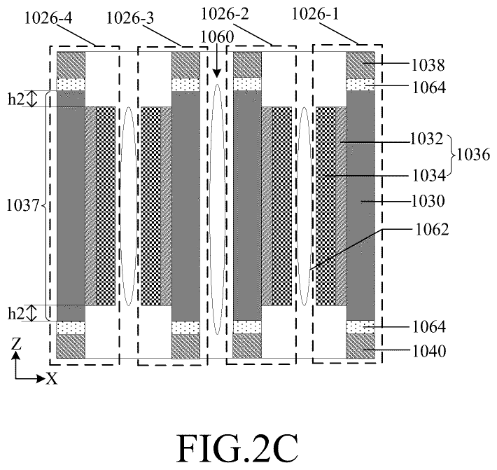

One of the architectures of a dynamic random access memory is described below in detail in conjunction with FIG. 2A. Before a memory device shown in FIG. 2A is described, directions that may be used in the following description are defined first. An extending direction of a semiconductor pillar is defined as a first direction (i.e., a Z direction). A second direction (i.e.,, an X direction) and a third direction (i.e., a Y direction) that intersect each other are defined in a plane perpendicular to a Z direction. In some implementations, an X direction, a Y direction, and the Z direction may be perpendicular to each other.

FIG. 2A is a cross-sectional view of a three-dimensional (3D) dynamic random access memory 100 including a vertical transistor according to an implementation of the present disclosure. As shown in FIG. 2A, the dynamic random access memory 100 includes a first device 102 and a second device 104 stacked over the first device 102 along a Z-axis direction. The first device 102 is connected with the second device 104 through a bonding interface 106. The first device 102 may be connected with the second device 104 by means of hybrid bonding, etc. In some implementations, the second device 104 may be bonded on a top of the first device 102 in a face-to-face manner at the bonding interface 106. The first device 102 may include a first substrate 1010, a peripheral circuit 1012 on a side of the first substrate 1010, and a first interconnect layer 1016 located on a side of the peripheral circuit 1012 away from the first substrate 1010. The first interconnect layer 1016 is configured to transmit an electrical signal of the peripheral circuit 1012. The peripheral circuit 1012 may include a plurality of transistors 1014. In some implementations, a trench isolation (e.g., a shallow trench isolation (STI)) and a doped area (e.g., a well, a source, and a drain of at least one of the transistors 1014) may be also formed on the first substrate 1010 or in the first substrate 1010.

The first device 102 may further include a first bonding layer 1018 at the bonding interface 106 and located on a side of the first interconnect layer 1016 away from the peripheral circuit 1012. The first bonding layer 1018 may include a plurality of first bonding contacts 1019 and a dielectric that electrically isolates the first bonding contacts 1019. The first bonding contacts 1019 in the first bonding layer 1018 and the surrounding dielectric may be configured for hybrid bonding. Relatively, the second device 104 may further include a second bonding layer 1020 at the bonding interface 106 and located on a side of the first bonding layer 1018 away from the first interconnect layer 1016. The second bonding layer 1020 may include a plurality of second bonding contacts 1021 and a dielectric that electrically isolates the second bonding contacts 1021. The second bonding contacts 1021 in the second bonding layer 1020 and the surrounding dielectric may be configured for hybrid bonding. Here, the second bonding contacts 1021 are in contact with the first bonding contacts 1019 at the bonding interface 106.

In some implementations, the peripheral circuit 1012 may further include a word line driver/row decoder coupled to word lines of a second interconnect layer 1022 through the second bonding contacts 1021 in the second bonding layer 1020 and the first bonding contacts 1019 in the first bonding layer 1018 and the first interconnect layer 1016. In some other implementations, the peripheral circuit 1012 may further include a bit line driver/column decoder coupled to bit lines 1023 of the second interconnect layer 1022 through the second bonding contacts 1021 in the second bonding layer 1020 and the first bonding contacts 1019 in the first bonding layer 1018 and the first interconnect layer 1016. Here, the second interconnect layer 1022 includes bit lines 1023 above the second bonding layer 1020, and the bit line 1023 is configured for transmitting an electrical signal. In some other implementations, the first device 102 and the second device 104 stacked may be not connected in a bonding manner, but instead are integrated on the same substrate (there is only the first substrate but no second substrate), and are directly connected through one or more interconnect layers between the first device 102 and the second device 104. In this case, neither of the first bonding layer 1018 and the first bonding contact 1019 exists in the first device 102. Neither of the second bonding layer 1020 and the second bonding contact 1021 exists in the second device 104. The bonding interface 106 between the first device 102 and the second device 104 does not exist either.

With reference to FIG. 2A, the second device 104 further includes a memory cell array on the second interconnect layer 1022. The memory cell array may include a plurality of memory cells 1024, a second substrate 1048 located on the memory cells 1024, and a third interconnect layer 1050 located on the second substrate 1048. A cross section of the dynamic random access memory 100 in FIG. 2A may be taken along a bit line direction (an X-axis direction), and one bit line 1023 in the second interconnect layer 1022 extending laterally in the X-axis direction may be coupled to a column of memory cells 1024.

Here, at least one of the memory cells 1024 may include a vertical transistor 1026 and a capacitor structure 1028 coupled to the vertical transistor 1026. The vertical transistor 1026 includes a semiconductor pillar 1030 extending vertically (in the Z-axis direction) and a gate structure 1036 in the bit line direction (the X-axis direction) and in contact with one side surface of the semiconductor pillar 1030. In some other implementations, the gate structure may completely surround the semiconductor pillar, half surround the semiconductor pillar, or be located on two opposite side surfaces of the semiconductor pillar, etc., which is no described in detail here. Here, the gate structure 1036 includes a gate electrode 1034 and a gate dielectric 1032 located between the gate electrode 1034 and the semiconductor pillar 1030 in the bit line direction (the X-axis direction). In some Implementations, the gate dielectric 1032 adjoins a side surface of the semiconductor pillar 1030, and the gate electrode 1034 adjoins the gate dielectric 1032.

In some Implementations, the semiconductor pillar 1030 has two end portions (an upper end portion and a lower end portion) in a vertical direction (the Z-axis direction). The vertical transistor 1026 may further include a source 1038 and a drain 1040 that are respectively disposed at the two end portions (the upper end portion and the lower end portion) of the semiconductor pillar 1030 in the vertical direction (the Z-axis direction) (the positions of the source and the drain are interchangeable, and an implementation in which the source 1038 is disposed at the upper end portion and the drain 1040 is disposed at the lower end portion is shown here and below). In some implementations, the source 1038 is coupled to the capacitor structure 1028 and the drain 1040 is coupled to the bit line 1023.

Since the gate electrode may be a part of the word line or extend as the word line in a word line direction, the second device 104 of the dynamic random access memory 100 may also include a plurality of word lines each extending in the word line direction (a Y-axis direction). Here, each word line 1034 may be coupled to one row of memory cells 1024.

The vertical transistor 1026 extends vertically through the word line 1034 and is in contact with the word line 1034, and the vertical transistor 1026 is in contact with the bit line 1023 at the drain 1040 of its lower end. Therefore, due to the vertical arrangement of the vertical transistor 1026, the word line 1034 and the bit line 1023 can be disposed in different planes in the vertical direction, which simplifies routing of the word line 1034 and the bit line 1023. Here, the vertical transistor 1026 may be arranged in a mirror-symmetrical manner so as to increase the density of the memory cells 1024 in the bit line direction (the X-axis direction). The two adjacent vertical transistors 1026 in the bit line direction are mirror-symmetrical to each other with respect to a trench isolation 1060, that is to say, the second device 104 may include a plurality of trench isolations 1060. At least one of the trench isolations 1060 and the word line 1034 extend in parallel in the word line direction (the Y-axis direction), and are disposed between two adjacent rows of semiconductor pillars 1030 of the vertical transistor 1026. In some implementations, the vertical transistors 1026 separated by the trench isolation 1060 are mirror-symmetrical with each other with respective to the trench isolation 1060. It should be understood that the trench isolation 1060 may include air gaps each laterally disposed between the adjacent semiconductor pillars 1030. The second device 104 further includes a plurality of gate isolations 1062. At least one of the gate isolations 1062 and the word line 1034 extend in parallel in the word line direction (the Y-axis direction), and are disposed between two adjacent rows of word lines 1034 of the vertical transistor 1026. It should be understood that sizes of the gate isolation 1062 and the word line 1034 in the bit line direction (the X-axis direction) may be the same as or different from a size of the trench isolation 1060 in the bit line direction (the X-axis direction). When the sizes of the gate isolation 1062 and the word line 1034 in the bit line direction (the X-axis direction) are different, spacings between the plurality of semiconductor pillars 1030 arranged along the bit line direction (the X-axis direction) are different. That is, the plurality of semiconductor pillars 1030 arranged along the bit line direction (the X-axis direction) are arranged nonuniformly.

As shown in FIG. 2A, the capacitor structure 1028 is located above the source 1038 (i.e., the upper end portion of the semiconductor pillar 1030) of the vertical transistor 1026 and is in contact with the source 1038. The capacitor structure 1028 may be a vertical capacitor.

As shown in FIG. 2A, the second device 104 may further include a capacitor contact 1047 in contact with a common plate of the vertical transistor 1026, which is configured for coupling a second electrode 1046 of the capacitor structure 1028 to the peripheral circuit 1012 or directly coupling it to the ground. In some implementations, a material forming an interlayer dielectric (ILD) layer of the capacitor structure 1028 includes, but is not limited to, silicon oxide. A configuration of the capacitor structure 1028 may include any suitable structure and configuration, for example, a planner capacitor, a stack capacitor, a multi-fin capacitor, a cylinder capacitor, a trench capacitor or a substrate-plate capacitor.

As shown in FIG. 2A, the vertical transistor 1026 extends vertically through the word line 1034 and is in contact with the word line 1034. The drain 1040 at the lower end portion of the vertical transistor 1026 is in contact with the bit line 1023, and the source 1038 at the upper end portion of the vertical transistor 1026 is in contact with the capacitor structure 1028. That is, due to the vertical arrangement of the vertical transistor 1026, the bit line 1023 and the capacitor structure 1028 can be disposed in different planes in the vertical direction, and coupled to opposite ends of the vertical transistor 1026 of the memory cell 1024 in the vertical direction. In some implementations, the bit line 1023 and the capacitor structure 1028 are disposed on opposite side faces of the vertical transistor 1026 in the vertical direction, which simplifies the routing of the bit line 1023 and reduces a coupling capacitance between the bit line 1023 and the capacitor structure 1028, compared with a memory cell where a bit line and a capacitor structure are disposed on the same side face of a planar transistor.

In some Implementations, the vertical transistor 1026 is disposed vertically between the capacitor structure 1028 and the bonding interface 106. That is, the vertical transistor 1026 may be arranged closer to the peripheral circuit 1012 of the first device 102 and the bonding interface 106 than the capacitor structure 1028. Since the bit line 1023 and the capacitor structure 1028 are coupled to the opposite end portions of the vertical transistor 1026, the bit line 1023 (serving as a part of the second interconnect layer 1022) is disposed vertically between the vertical transistor 1026 and the bonding interface 106 to reduce an interconnect routing distance and complexity.

In some Implementations, the second device 104 further includes the second substrate 1048 disposed above the memory cell 1024, and a pad-out third interconnect layer 1050 above the memory cell 1024. The pad-out third interconnect layer 1050 may include interconnects (e.g., a contact pad 1054) in one or more ILD layers.

In some Implementations, the second device 104 further includes one or more contacts 1052 that extend through a part of the pad-out third interconnect layer 1050 and the second substrate 1048 to couple the pad-out third interconnect layer 1050 to the memory cell 1024 and the second interconnect layer 1022. In this way, the peripheral circuit 1012 can be coupled to the memory cell 1024 through the first interconnect layer 1016 and the second interconnect layer 1022 and the second bonding layer 1020 and the first bonding layer 1018, and the peripheral circuit 1012 and the memory cell 1024 can be coupled to an external circuit through the contact 1052 and the pad-out third interconnect layer 1050.

With reference to FIG. 2A and FIG. 2B, in some implementations, to mitigate a hot carrier inject (HCI) effect, lightly doped drains (LDD) 1064 are formed at the two end portions (the upper end portion and the lower end portion) of the semiconductor pillar 1030.

In an implementation, after the gate structure 1036 is formed on a side of the semiconductor pillar 1030, a lightly doped drain 1064 is formed at the upper end portion of the semiconductor pillar 1030 by using a diffusion process, and a lightly doped drain 1064 is formed at the lower end portion of the semiconductor pillar 1030 by using an ion implantation process.

Because it is difficult to control the position and depth of the lightly doped drain 1064, the alignment difficulty between the lightly doped drain 1064 and the gate structure 1036 is increased. In some Implementations, as shown in FIG. 2B, excessive overlap regions exist between the lightly doped drain 1064 and the gate structure 1036. In an implementation, a height of an overlap region between the lightly doped drain 1064 at the upper end portion of the semiconductor pillar 1030 and the gate structure 1036 in the Z-axis direction is h1. When h1 is excessively large, the risk of a gate induced drain leakage (GIDL) current effect is increased, and a short circuit between the bit line 1023 and the word line/gate electrode 1034 or between the word line/gate electrode 1034 and the capacitor structure 1028 in FIG. 2A may occur.

FIG. 2C is a partial schematic structural diagram of a dynamic random access memory according to an implementation of the present disclosure. FIG. 2C is an enlarged schematic diagram at a respective position of a region A in FIG. 2A. As shown in FIG. 2C, in other Implementations, no overlap region exists between the lightly doped drain 1064 and the gate structure 1036 in the Z-axis direction. However, a spacing between a bottom surface of the lightly doped drain 1064 at the upper end portion of the semiconductor pillar 1030 and a top surface of the gate structure 1036 in the Z-axis direction is h2, and a spacing between a top surface of the lightly doped drain 1064 at the lower end portion of the semiconductor pillar 1030 and a bottom surface of the gate structure 1036 in the Z-axis direction is h2. In other words, the gate structure 1036 has a vertical size less than a vertical size (e.g., a depth in the Z-axis direction) of the semiconductor pillar 1030. When h2 is excessively large, the control capability of a channel area 1037 (a region other than the lightly doped drain 1064 between the source 1038 and the drain 1040) by the gate structure 1036 is reduced, and as a result the performance and reliability of the memory device are reduced.

In some Implementations, as shown in FIG. 2B and FIG. 2C, the dynamic random access memory includes a plurality of vertical transistors (1026-1, 1026-2, 1026-3, and 1026-4). To prevent mutual coupling between adjacent transistors, an isolation structure (for example, a trench 1060) is usually configured to reduce the mutual coupling between the adjacent transistors. For example, in the architecture of the dynamic random access memory shown in FIG. 2A, to prevent mutual coupling between back-to-back adjacent transistors (the vertical transistor 1026-2 and the vertical transistor 1026-3 shown in FIG. 2B and FIG. 2C), a trench isolation 1060 including a metal shielding layer is usually configured to reduce the mutual coupling between the back-to-back adjacent transistors. However, as the integration level of the memory device keeps increasing, the volume and key size of the memory device keep decreasing, and a distance between adjacent transistors also decreases. The manufacturing process is high in difficulty and the manufacturing cost is high for arranging a metal shielding structure, which is adverse to size shrink of the memory device in future.

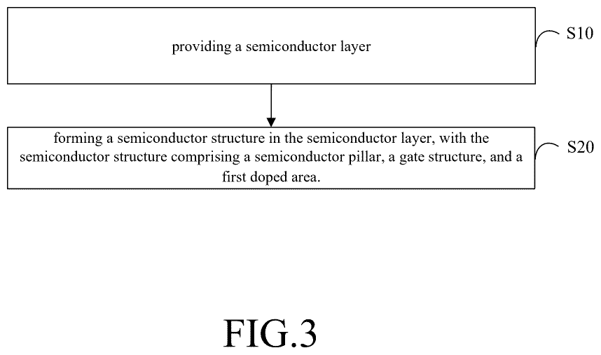

Based on this, to solve one or more of the above problems, Implementations of the present disclosure further provide a manufacturing method of a memory device. With reference to FIG. 3, FIG. 3 is a schematic flow diagram of a manufacturing method of a memory device according to an implementation of the present disclosure. The method includes the following operations.

Operation S10: Providing a semiconductor layer.

Operation S20: Forming a semiconductor structure in the semiconductor layer, with the semiconductor structure including a semiconductor pillar, a gate structure, and a first doped area.

The memory device may include a plurality of semiconductor structures. An implementation in which the memory device includes a plurality of semiconductor structures is described here and below.

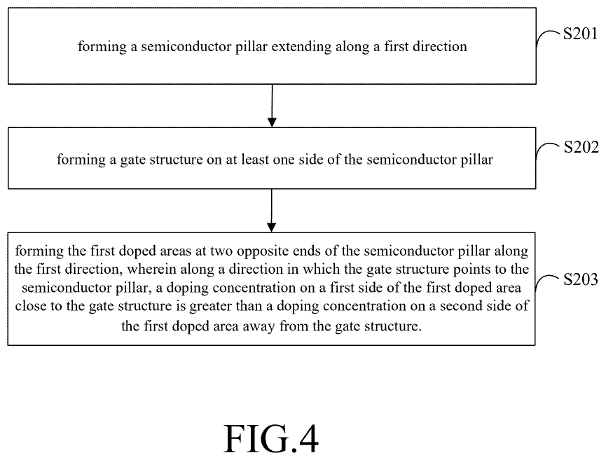

FIG. 4 is a schematic flow diagram of a formation method of a semiconductor structure according to an implementation of the present disclosure. As shown in FIG. 3 and FIG. 4, forming the semiconductor structure in Operation S20 in FIG. 3 includes the following operations.

Operation S201: Forming a semiconductor pillar extending along a first direction.

Operation S202: Forming a gate structure on at least one side of the semiconductor pillar.

Operation S203: Forming the first doped areas at two opposite ends of the semiconductor pillar along the first direction, wherein along a direction in which the gate structure points to the semiconductor pillar, a doping concentration on a first side of the first doped area close to the gate structure is greater than a doping concentration on a second side of the first doped area away from the gate structure.

The operations shown in FIG. 4 are not exclusive, and additional operations may also be performed before and after any operation or between any operations in the shown operations. A sequence of the operations shown in FIG. 4 may be adjusted according to actual requirements.

As described above, the gate structure and the semiconductor pillar in the memory device may have a variety of different relative positions, and different relative positions correspond to different particular manufacturing manners. In Implementations of the present disclosure, an implementation in which two gate structures corresponding to two adjacent semiconductor pillars are respectively disposed back to back (the back-to-back arrangement is shown in FIG. 2A) is described as an example. Based on this, the memory device may include a plurality of semiconductor pillars arranged in an array along an X-axis direction and a Y-axis direction. However, it should be understood that, the formation method of the semiconductor structure below is only used to describe the present disclosure, and is not used to limit the scope of the present disclosure.

There are various methods of forming the semiconductor pillar, the gate structure, and the first doped area, and several methods are shown in the Implementations of the present disclosure. Processes of forming the semiconductor pillar, the gate structure, and the first doped area in the memory device are described below in detail in conjunction with the drawings.

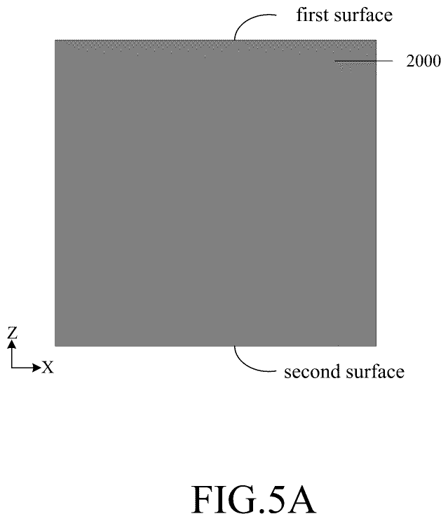

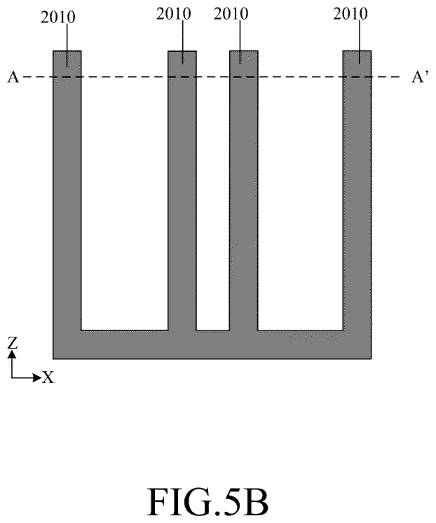

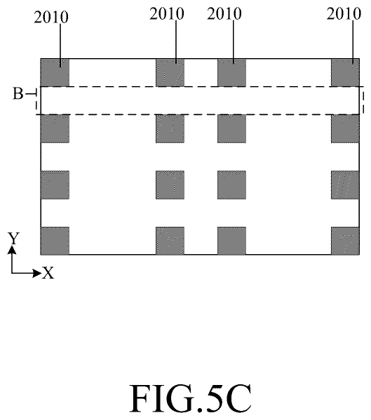

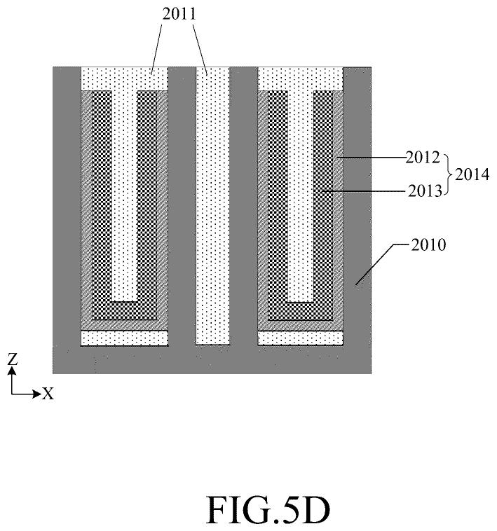

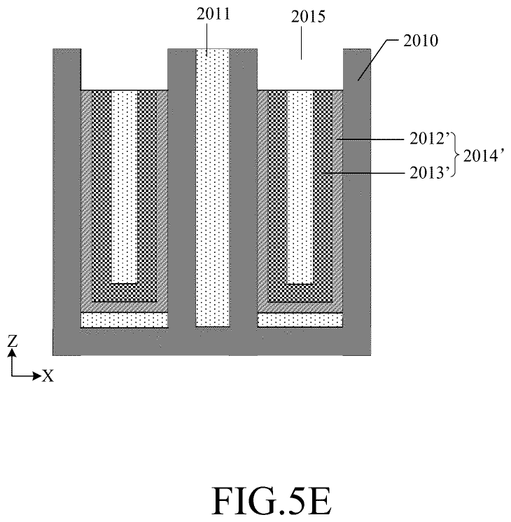

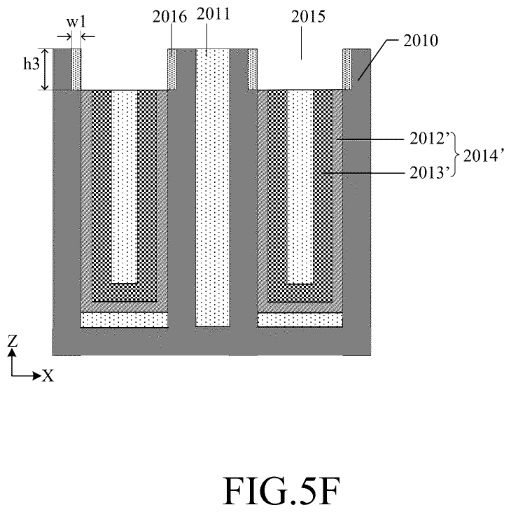

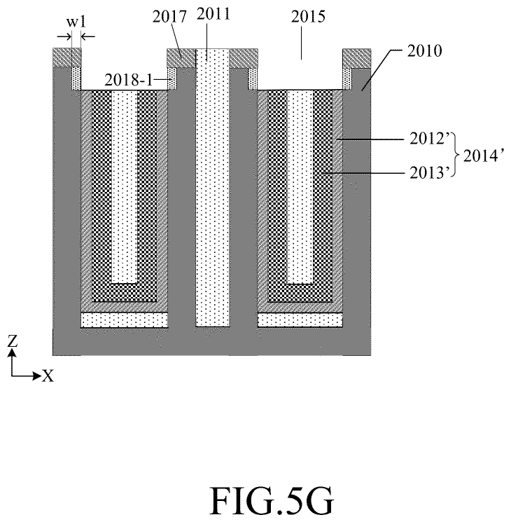

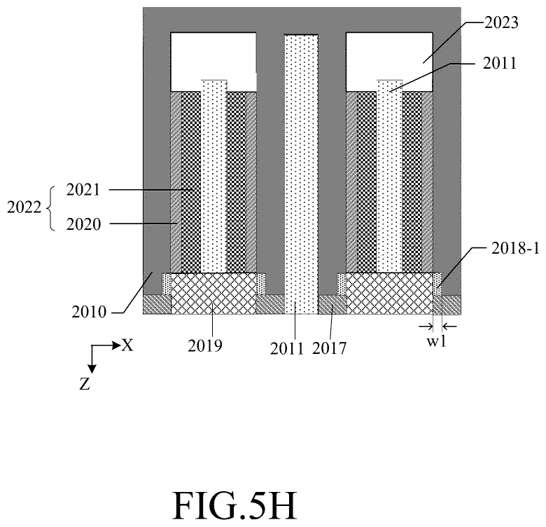

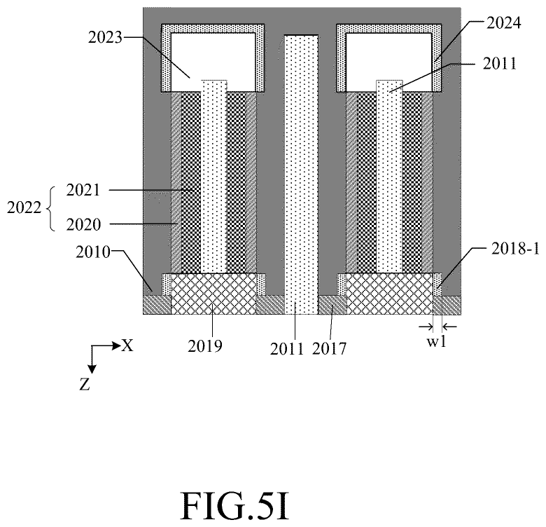

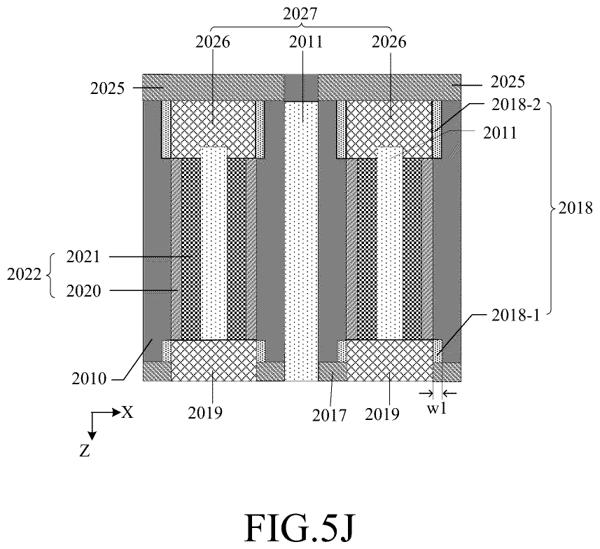

FIG. 5A to FIG. 5C are schematic cross-sectional views of a process of forming a semiconductor pillar according to an implementation of the present disclosure. FIG. 5C is a schematic cross-sectional view along an AA′ direction in FIG. 5B. A process of forming a plurality of semiconductor pillars is described below in detail in conjunction with the drawings.

With reference to FIG. 5A, a semiconductor layer 2000 is provided. The semiconductor layer 2000 has a first surface and a second surface that are opposite along the first direction (i.e., a Z direction). A material of the semiconductor layer 2000 may include a semiconductor material, for example, silicon. In an implementation, the material of the semiconductor layer 2000 may include monocrystalline silicon.

With reference to FIG. 5B and FIG. 5C, a plurality of semiconductor pillars 2010 arranged in a form of an array are formed in the semiconductor layer 2000, and the semiconductor pillars 2010 extend along the first direction. In some Implementations, a method of forming the semiconductor pillars 2010 may include: forming a plurality of trenches extending along the X-axis direction in the semiconductor layer 2000, filling the trenches with an insulation material (e.g., silicon oxide), and then forming a plurality of trenches extending along the Y-axis direction in the semiconductor layer 2000. The trenches extending along the Y-axis direction are adjusted according to the relative position between the gate structure and the semiconductor pillar. FIG. 5B shows that the trenches extending along the Y-axis direction include trenches that are disposed alternately and have different sizes when two gate structures corresponding to two adjacent semiconductor pillars are respectively disposed back to back. The remaining insulation material filling the trenches previously is removed to form the semiconductor pillars 2010 arranged in a form of the array.

Cross sections of the semiconductor pillars 2010 shown in FIG. 5C along an X axis and a Y axis are square. The shape is only used as an example, and is not used to limit the shapes of the cross sections of the semiconductor pillars. The shape of the cross section of the semiconductor pillar may further include rectangle, circle, ellipse, and similar shapes of these shapes, etc.

In some other Implementations, a method of forming the semiconductor pillars 2010 may further include: forming a plurality of trenches extending along the Y-axis direction in the semiconductor layer 2000, filling the trenches with an insulation material (e.g., silicon oxide), and then forming a plurality of trenches extending along the X-axis direction in the semiconductor layer 2000.

In some Implementations, the trenches along at least one of the X-axis direction or a Y direction may be formed through a lithographic process (which may be construed as lithography-etch (LE) here and below). A method of filling the insulation material in the trenches may include, but is not limited to, physical vapor deposition (PVD), chemical vapor deposition (CVD), atomic layer deposition (ALD), among other processes.

In some Implementations, forming the gate structure and the first doped area includes: forming a first initial gate covering at least one side of the semiconductor pillar; removing parts of the first initial gate from a first surface and a second surface of the semiconductor layer along the first direction, respectively, to form the gate structure and expose a part of the semiconductor pillar, wherein the first surface and the second surface are two opposite surfaces of the semiconductor layer along the first direction; and forming the first doped areas from surfaces of exposed parts of the semiconductor pillar, respectively, in a region extending a first preset size along a direction perpendicular to the first direction.

FIG. 5D to FIG. 5J are cross sectional schematic views of a process of forming a gate structure and a first doped area according to an implementation of the present disclosure.

With reference to FIG. 5D, a first dielectric layer 2011 and a first initial gate 2014 covering at least one side of the semiconductor pillar are formed in the trenches extending along the Y-axis direction. It can be understood that, the first dielectric layer 2011 between adjacent semiconductor pillars 2010 here has a function similar to that of the trench isolation 1060 in FIG. 2A. In an implementation, a material of the first dielectric layer 2011 includes silicon oxide.

In some Implementations, the first initial gate 2014 may include an initial gate electrode 2013 and an initial gate dielectric 2012. In some Implementations, the first initial gate 2014 may further include a barrier layer located between the initial gate electrode 2013 and the initial gate dielectric 2012. A material of the initial gate electrode 2013 may include, but is not limited to, tungsten. A material of the initial gate dielectric 2012 includes, but is not limited to, silicon oxide. A material of the barrier layer includes, but is not limited to, titanium nitride.

In some Implementations, a method of forming the first initial gate 2014 includes, but is not limited to, deposition, etching, and other processes; and a method of forming the first dielectric layer 2011 includes, but is not limited to, PVD, CVD, ALD, and other processes.

In some Implementations, forming the first doped area includes: forming first portions and second portions of the first doped areas from surfaces of exposed parts of the semiconductor pillar, respectively, in a region extending the first preset size along a direction perpendicular to the first direction by using a molecular layer deposition (MLD) process or a rapid vapor deposition (RVD) process.

With reference to FIG. 5E, in some Implementations, a part of the first initial gate is removed from the first surface of the semiconductor layer along the first direction, and a third initial gate 2014′ and an opening 2015 are formed, to expose a part of the semiconductor pillar 2010. In some Implementations, a method of removing a part of the first initial gate includes, but is not limited to, dry etching. The third initial gate 2014′ may include an intermediate gate electrode 2013′ and an intermediate gate dielectric 2012′.

With reference to FIG. 5F, a first initial portion 2016 of the first doped area is formed from a surface of the exposed part of the semiconductor pillar 2010 in a region extending a first preset size w1 along a direction perpendicular to the first direction.

In some implementations, the first initial portion 2016 of the first doped area is formed in a region extending the first preset size w1 along a direction perpendicular to the first direction by using a molecular layer deposition process or a rapid vapor deposition process. In an implementation, the first initial portion 2016 of the first doped area is formed by using a boron (B)-containing first dopant through a molecular layer deposition process, or the first initial portion 2016 of the first doped area is formed by using a phosphorus (P)-containing second dopant through a rapid vapor deposition process.

In some Implementations, a spacing between an end surface of the third initial gate 2014′ close to the first initial portion 2016 of the first doped area and an end surface of the first initial portion 2016 of the first doped area close to the third initial gate 2014′ along the first direction is less than or equal to a first preset threshold.

It may be understood that when a height of an overlap region between the first initial portion 2016 of the first doped area and the third initial gate 2014′ in a Z-axis direction is less than or equal to the first preset threshold, the risk of a GIDL effect is greatly reduced.

The third initial gate 2014′ and the opening 2015 formed by removing a part of the first initial gate provide an accurate positioning reference for forming the first initial portion 2016 of the first doped area. Furthermore, a material of a surface of the part of the semiconductor pillar 2010 exposed by the opening 2015 and a material of the third initial gate 2014′ are significantly different. Therefore, the third initial gate 2014′ may serve as a barrier layer or stop layer in a process of forming the first initial portion 2016 of the first doped area, such that a formation position of the first initial portion 2016 of the first doped area is highly aligned with a position of the third initial gate 2014′ in the first direction.

It may be understood that a size h3 of the first initial portion 2016 of the first doped area in FIG. 5F in the first direction (a Z direction) is related to a depth of the opening 2015. In an implementation, the size h3 of the first initial portion 2016 of the first doped area in the first direction (a Z direction) is equal to the depth of the opening 2015.

A photomask does not need to be used to define a doping region in the molecular layer deposition process and the rapid vapor deposition process. Therefore, an impact caused by a photoetching alignment error can be avoided, such that the alignment precision between the first doped area and the gate structure formed in a subsequent process can be improved. Further, the deposition of a material is implemented by controlling surface chemical reactions in the molecular layer deposition process and the rapid vapor deposition process, and can be performed under very precise conditions. The precise control of the formation position of the doping region can be implemented by adjusting reaction conditions. In an implementation, the first initial portion 2016 of the first doped area formed along the opening 2015 by using a molecular layer deposition process or a rapid vapor deposition process may be considered as an ultra-shallow junction. The first preset size w1 is a junction depth of the ultra-shallow junction, and the first preset size w1 may be controlled through process parameters (temperature, or concentration, etc.).

During practical application, the first preset size w1 is mainly related to a radial width of the semiconductor pillar 2010. When the radial width of the semiconductor pillar 2010 is larger, the first preset size w1 may also be set larger.

In some implementations, a range of a ratio of the radial width of the semiconductor pillar to the first preset size w1 is 1-10. In an implementation, the ratio of the radial width of the semiconductor pillar to the first preset size w1 may be 1, 5, or 10. When the ratio of the radial width of the semiconductor pillar to the first preset size w1 is 1, it indicates that a size of the first doped area in an X direction is equal to the radial width of the semiconductor pillar.

The above-mentioned range of the ratio of the radial width of the semiconductor pillar 2010 to the first preset size w1 is only for exemplary description, and is not used to limit the range of the ratio of the radial width of the semiconductor pillar 2010 to the first preset size w1 in the Implementations of the present disclosure.

In some implementations, a range of the first preset size w1 is 5 nm to 10 nm. In an implementation, the first preset size w1 may be 5 nm, 7 nm, or 10 nm.

As shown in FIG. 5F, in some Implementations, along a direction in which the third initial gate 2014′ points to the semiconductor pillar 2010 in the semiconductor structure, a doping concentration on a first side of the first initial portion 2016 of the first doped area close to the third initial gate 2014′ is greater than a doping concentration on a second side of the first initial portion 2016 of the first doped area away from the third initial gate 2014′.

In some Implementations, a doping concentration of the first initial portion 2016 of the first doped area decreases along the direction in which the third initial gate 2014′ points to the semiconductor pillar 2010. The doping concentration of the first initial portion 2016 of the first doped area has a concentration gradient in the X direction, which helps to reduce an electric field in a horizontal direction (an X direction), and improves the performance and reliability of the memory device.

With reference to FIG. 5G, a part of the first initial portion 2016 away from the third initial gate 2014′ is doped from the first surface of the semiconductor layer along the first direction by using an ion implantation process, the doped portion forms a source 2017, and the remaining first initial portion that is not doped by using an ion implantation process forms a first portion 2018-1 of the first doped area. In some implementations, the smallest doping concentration of the source 2017 is greater than the largest doping concentration of the first portion 2018-1 of the first doped area.

With reference to FIG. 5G and FIG. 5H, after forming the source 2017 and the first portion 2018-1 of the first doped area, the semiconductor layer is turned over. A part of the third initial gate 2014′ is removed from the second surface of the semiconductor layer along the first direction, and a gate structure 2022 and a cavity 2023 are formed, so as to expose a part of the semiconductor pillar 2010.

In some implementations, the gate structure 2022 includes a gate electrode 2021 and a gate dielectric 2020.

In some implementations, as shown in FIG. 5G and FIG. 5H, after the source 2017 and the first portion 2018-1 of the first doped area are formed, a dielectric material is filled in the opening 2015, to form a second dielectric layer 2019, the semiconductor layer is turned over, and the back of the semiconductor layer is thinned. A material of the second dielectric layer 2019 and a material of the first dielectric layer 2011 may be the same or may be different. For example, the material of the second dielectric layer 2019 and the material of the first dielectric layer 2011 are both silicon oxide.

In some implementations, a plurality of trenches extending along the X direction and arranged along the Y direction may be formed on the back (the second surface) of the semiconductor layer. At least one of the trenches is located between the semiconductor pillars 2010 adjacent along the Y direction. A formation position of the trench may refer to the position of a region B in FIG. 5C for understanding. Through the above-mentioned trenches, a part of the third initial gate 2014′ is removed, and the gate structure 2022 and the cavity 2023 are formed, to expose a part of the semiconductor pillar 2010.

With reference to FIG. 5I, a second initial portion 2024 of the first doped area is formed from a surface of the exposed part of the semiconductor pillar 2010 in a region extending the first preset size w1 along a direction perpendicular to the first direction.

With reference to FIG. 5I-5J, a partial region of the second initial portion 2024 away from the gate structure 2022 is doped from the second surface of the semiconductor layer along the first direction by using an ion implantation process, the doped partial region forms a drain 2025, and the remaining second initial portion 2024 that is not doped by using an ion implantation process forms a second portion 2018-2 of the first doped area.

In some implementations, the smallest doping concentration of the drain 2025 is greater than the largest doping concentration of the second portion 2018-2 of the first doped area.

In some implementations, a dielectric material is filled in the cavity 2023 to form a third dielectric layer 2026, to prevent the semiconductor structure from collapsing, thereby enhancing a support effect. As shown in FIG. 5J, the third dielectric layer 2026, the second dielectric layer 2019, and the remaining the first dielectric layer 2011 form a dielectric layer 2027. A first doped area 2018 includes the first portion 2018-1 of the first doped area and the second portion 2018-2 of the first doped area.

In any semiconductor structure in the memory device shown in FIG. 5J, along a direction in which the gate structure 2022 points to the semiconductor pillar 2010, a doping concentration on a first side of the first doped area 2018 close to the gate structure 2022 is greater than a doping concentration on a second side of the first doped area 2018 away from the gate structure 2022.

In any semiconductor structure in the memory device shown in FIG. 5J, a doping concentration of the first doped area 2018 decreases along the direction in which the gate structure 2022 points to the semiconductor pillar 2010.

In some Implementations, a spacing (refer to h1 in FIG. 2B for understanding) between an end surface of the gate structure 2022 close to the first portion 2018-1 and an end surface of the first portion 2018-1 close to the gate structure 2022 along the first direction and a spacing (refer to h1 in FIG. 2B for understanding) between an end surface of the gate structure 2022 close to the second portion 2018-2 and an end surface of the second portion 2018-2 close to the gate structure 2022 are both less than or equal to the first preset threshold.

Through the method in Implementations of the present disclosure, the alignment precision between the first doped area and the gate structure is improved. In the first direction, a spacing between a bottom surface of the first portion of the first doped area located at a first end of the semiconductor pillar and a top surface of the gate structure and a spacing between a top surface of the second portion of the first doped area located at a second end of the semiconductor pillar and a bottom surface of the gate structure are both less than or equal to the first preset threshold. In this way, the reliability of the memory device can be improved. It should be understood that the alignment here needs to exclude slight deviations caused by manufacturing errors or the like.

In some Implementations, a range of the first preset threshold is 5 nm to 10 nm. In an implementation, the first preset threshold is 5 nm, 7 nm, or 10 nm.

It is to be noted that h1 in FIG. 2B and h2 in FIG. 2C are both far greater than the first preset threshold.

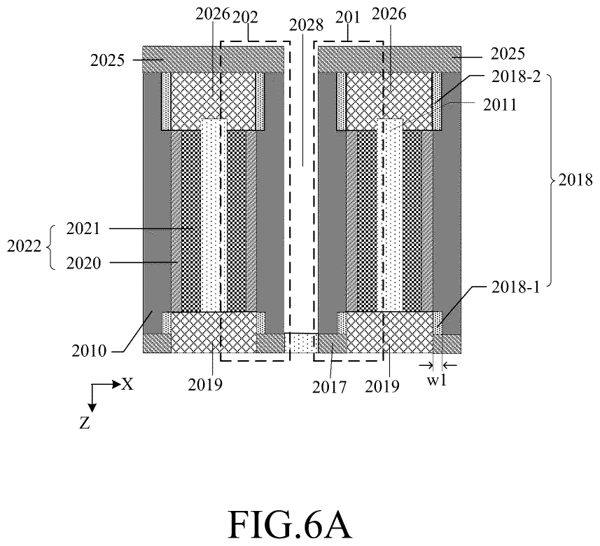

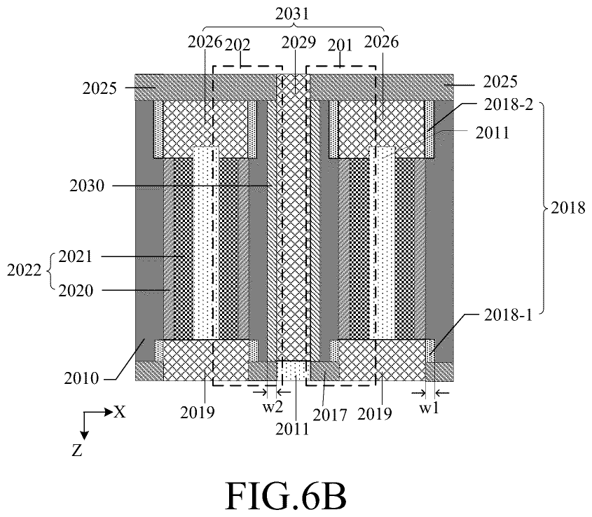

FIG. 6A and FIG. 6B are cross sectional schematic views of another process of forming a memory device according to an implementation of the present disclosure. After the operation of FIG. 5J, with reference to FIG. 6A, a part of the dielectric layer 2027 between the semiconductor pillars 2010 of a first semiconductor structure 201 and a second semiconductor structure 202 of the memory device is removed. In an implementation, a part of the first dielectric layer 2011 between the semiconductor pillars 2010 of the first semiconductor structure 201 and the second semiconductor structure 202 is removed, and an opening 2028 is formed to expose partial surfaces of the semiconductor pillars of the first semiconductor structure 201 and the second semiconductor structure 202.

With reference to FIG. 6B, a second doped area 2030 is formed in a region extending a second preset size w2 along a direction perpendicular to the first direction by using a molecular layer deposition process or a rapid vapor deposition process. Subsequently, a dielectric material is filled in the opening exposing the semiconductor pillars of the first semiconductor structure 201 and the second semiconductor structure 202 to form a fourth dielectric layer 2029. The fourth dielectric layer 2029, the third dielectric layer 2026, the second dielectric layer 2019, and the remaining the first dielectric layer 2011 form a dielectric layer 2031.

As shown in FIG. 6B, the second doped area 2030 extends the second preset size w2 from a side surface in contact with a dielectric layer (the fourth dielectric layer 2029) toward the gate structure 2022, and a doping type of the second doped area is different from doping types of both the source 2017 and the drain 2025.

In the practical applications, the second preset size w2 is mainly related to the radial width of the semiconductor pillar 2010. When the radial width of the semiconductor pillar 2010 is larger, the second preset size w2 may also be set larger.

In some implementations, the first preset size w1 and the second preset size w2 may be the same, or may be different.

In some implementations, a range of a ratio of the radial width of the semiconductor pillar 2010 to the second preset size w2 is 2-7. In an implementation, the ratio of the radial width of the semiconductor pillar to the second preset size w2 may be 2, 3, 4, 5, 6, or 7.

In some implementations, when the radial width of the semiconductor pillar is 10-20 nm, a range of the second preset size w2 is 1 nm to 10 nm. Further, in an implementation, the second preset size w2 may be 1 nm, 5 nm, or 10 nm.

The above-mentioned range of the ratio of the radial width of the semiconductor pillar 2010 to the second preset size w2 is only for exemplary description, and is not used to limit the range of the ratio of the radial width of the semiconductor pillar 2010 to the second preset size w2 in the examples of the present disclosure.

In some Implementations, the smallest doping concentrations of the source 2017 and the drain 2025 are both greater than the largest doping concentration of the second doped area 2030.

In some Implementations, the doping types of the source 2017 and the drain 2025 are an N type, and the doping type of the second doped area 2030 is a P type.

In Implementations of the present disclosure, a second doped area that has a doping type different from those of the source and the drain and extends the second preset size from a side surface in contact with the dielectric layer toward the gate structure is disposed in the semiconductor pillars of adjacent semiconductor structures. When one of the first semiconductor structure and the second semiconductor structure is turned on, a channel area of the semiconductor structure that is turned on turns into a high voltage. The second doped area is disposed to form a barrier layer, such that electrons can be prevent from easily passing through the channel area of the transistor semiconductor structure that is turned on to move toward the dielectric layer and enter a channel area of another semiconductor structure to affect the another semiconductor structure. In this way, a coupling effect between the first semiconductor structure and the second semiconductor structure that are adjacently disposed in the semiconductor structure can be improved, and size shrink of the memory device in future is better facilitated.

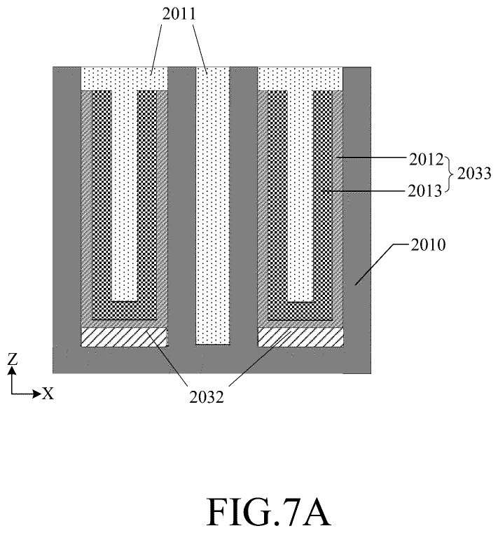

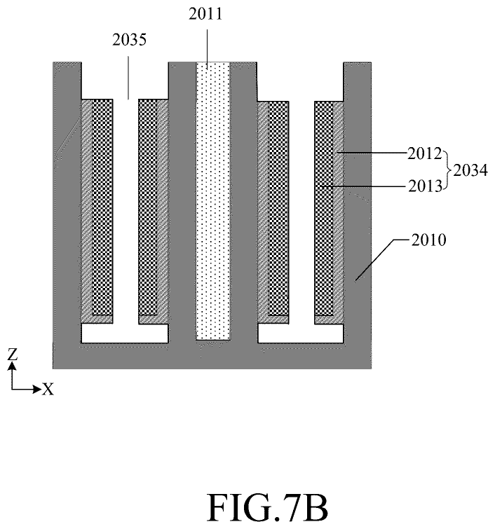

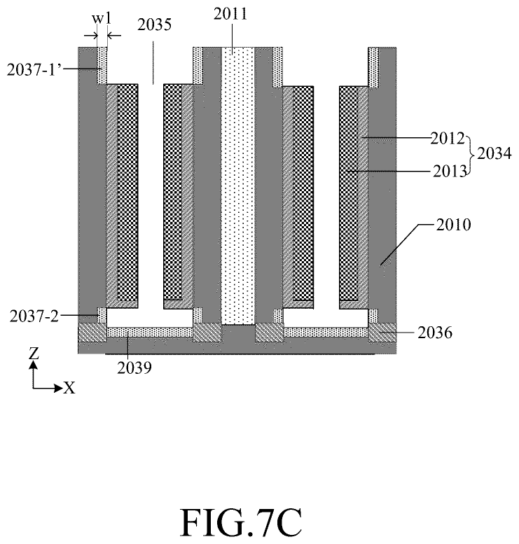

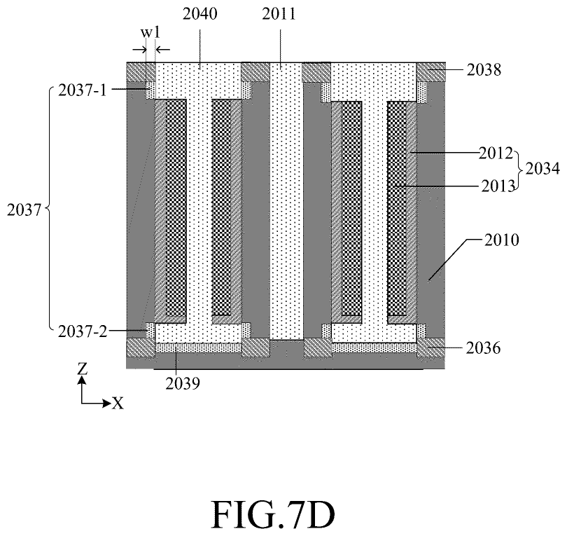

FIG. 7A to FIG. 7D are cross sectional schematic views of another process of forming a memory device according to an implementation of the present disclosure.

With reference to the method and related description in FIG. 5A to FIG. 5C, the semiconductor pillar 2010 is formed.

Next, with reference to FIG. 7A, a sacrificial layer 2032 is formed at a bottom of at least one side of the semiconductor pillar 2010, and the sacrificial layer 2032 is formed at the bottom of at least one side of the semiconductor pillar; and a second initial gate 2033 covering respective side of the semiconductor pillar 2010 is formed on the sacrificial layer 2032, and the second initial gate 2033 may include an initial gate electrode 2013 and an initial gate dielectric 2012. The structure and composition of the second initial gate 2033 here may refer to the first initial gate 2014 in FIG. 5D for understanding.

Following FIG. 5C, the first dielectric layer 2011 shown in FIG. 7A is formed in the trenches extending along the Y-axis direction. It can be understood that, the first dielectric layer 2011 between adjacent semiconductor pillars 2010 in FIG. 7A has a function similar to that of the trench isolation 1060 in FIG. 2A. In an implementation, a material of the first dielectric layer 2011 includes silicon oxide.

With reference to FIG. 7A and FIG. 7B, top portions of the second initial gate 2033 and the sacrificial layer 2032 are removed, to form a gate structure 2034 and an opening 2035, and expose a top and a bottom of a respective side surface of the semiconductor pillar 2010. In some implementations, a material of the sacrificial layer 2032 includes, but is not limited to, silicon nitride or silicon oxynitride, etc.

In some Implementations, the first doped area is formed from a surfaces of exposed parts of the semiconductor pillar, respectively, in a region extending the first preset size along a direction perpendicular to the first direction.

In some Implementations, forming the first doped area includes: forming first portions and second portions of the first doped area from surfaces of exposed parts of the semiconductor pillar, respectively, in a region extending the first preset size along a direction perpendicular to the first direction by using a molecular layer deposition process or a rapid vapor deposition process.

With reference to FIG. 7C, a drain 2036 is formed at the bottom of at least one side of the semiconductor pillar 2010 by using a diffusion process; and a first initial portion 2037-1′ and a second portion 2037-2 of the first doped area are respectively formed from surfaces of exposed parts of the semiconductor pillar 2010 at a top and a bottom of a respective side surface in a region extending the first preset size w1 along a direction perpendicular to the first direction.

While forming the first initial portion 2037-1′ and the second portion 2037-2 of the first doped area, respectively, from surfaces of exposed parts of the semiconductor pillar 2010 at a top and a bottom of a respective side surface along the opening 2035 by using a molecular layer deposition process or a rapid vapor deposition process, a third portion 2039 is also formed between the drains 2036 at the bottom of the opening 2035, and in subsequent processes, the drain 2036 and the third portion 2039 are connected with a bit line. With reference to FIG. 7D, a partial region of the first initial portion away from the gate structure 2034 is doped from a top of the semiconductor layer along the first direction by using an ion implantation process, the doped partial region forms a source 2038, and the remaining first initial portion that is not doped by using an ion implantation process forms a first portion 2037-1 of the first doped area.

In some implementations, after the drain, the source, and the first doped area are formed, a dielectric material is filled in the opening, to form a fifth dielectric layer 2040. A material of the fifth dielectric layer 2040 includes, but is not limited to, silicon oxide. In Implementations of the present disclosure, during the formation of the gate structure, a part of the surface of the semiconductor pillar is exposed by removing an initial gate (the first/second/third initial gate) to provide a positioning reference for a formation position of the first doped area, thereby improving the alignment precision of the first doped area and the gate structure, reducing the alignment difficulty of the first doped area and the gate structure, and improving the reliability of the memory device. In another aspect, the doping concentration on the first side of the first doped area close to the gate structure is greater than the doping concentration on the second side of the first doped area away from the gate structure, which helps to reduce an electric field in a horizontal direction (an X direction), and improves the performance and reliability of the memory device.

A case in which the semiconductor pillar has a vertically consistent size on a Z axis is shown in the Implementations of the present disclosure. However, the shape is only used as an example, and is not used to limit a size of the semiconductor pillar on the Z axis, and a case that the formed semiconductor pillar has a decreasing width from top to bottom due to a manufacturing process deviation or another factor is not excluded.

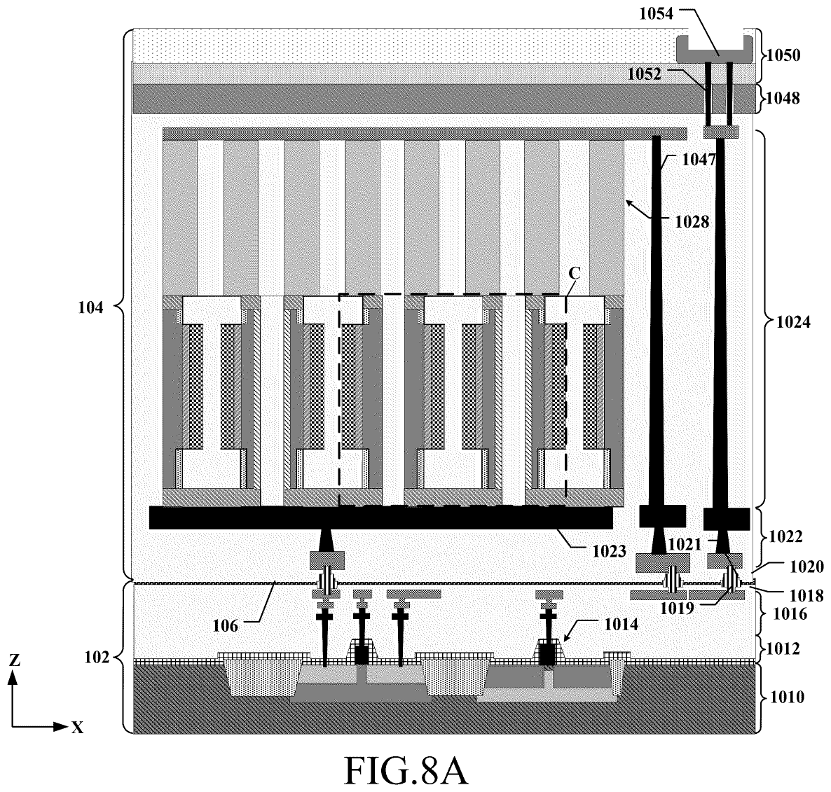

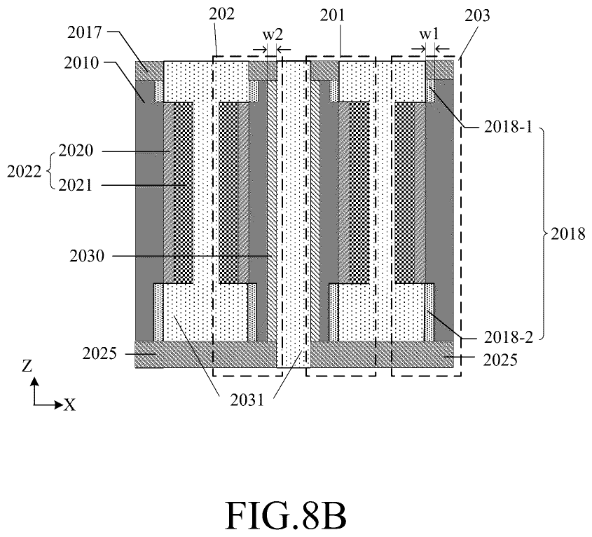

Implementations of the present disclosure further provide a memory device. FIG. 8A is a schematic structural diagram of a memory device according to an implementation of the present disclosure. The architecture of the memory device shown in FIG. 8A has the same structure as that shown in FIG. 2, and it may refer to related description of FIG. 2A for understanding. The structure of a vertical transistor (a semiconductor structure) in FIG. 8A is different from the vertical transistor 1026 in FIG. 2A.

FIG. 8B is an enlarged schematic diagram of a region C in FIG. 8A. As shown in FIG. 8B, the memory device includes: a semiconductor structure, the semiconductor structure including: a semiconductor pillar 2010 extending along a first direction; a gate structure 2022 located on at least one side of the semiconductor pillar 2010; and a first doped area 2018 located at two opposite ends of the semiconductor pillar 2010 along the first direction, wherein along a direction in which the gate structure 2022 points to the semiconductor pillar 2010, a doping concentration on a first side of the first doped area 2018 close to the gate structure 2022 is greater than a doping concentration on a second side of the first doped area 2018 away from the gate structure 2022.

In some Implementations, the gate structure 2022 includes a gate electrode 2021 and a gate dielectric 2020. In some Implementations, the gate structure 2022 may further include a barrier layer located between the gate electrode 2021 and the gate dielectric 2020. A material of the gate electrode may include, but is not limited to, tungsten. A material of the gate dielectric includes, but is not limited to, silicon oxide. A material of the barrier layer includes, but is not limited to, titanium nitride.

The doping concentration on the first side of the first doped area close to the gate structure is greater than the doping concentration on the second side of the first doped area away from the gate structure, which helps to reduce an electric field in a horizontal direction (an X direction), and improves the performance and reliability of the memory device.

In some Implementations, a doping concentration of the first doped area 2018 decreases along the direction in which the gate structure 2022 points to the semiconductor pillar 2010.

In some Implementations, the first doped area includes a first portion 2018-1 located at a first end of the semiconductor pillar 2010 and a second portion 2018-2 located at a second end of the semiconductor pillar 2010, and the first end and the second end are the two opposite ends of the semiconductor pillar along the first direction; wherein a spacing between an end surface of the gate structure 2022 close to the first portion 2018-1 and an end surface of the first portion 2018-1 close to the gate structure 2022 along the first direction and a spacing between an end surface of the gate structure 2022 close to the second portion 2018-2 and an end surface of the second portion 2018-2 close to the gate structure 2022 are both less than or equal to a first preset threshold.

In some Implementations, a range of the first preset threshold is 5 nm to 10 nm. In an implementation, the first preset threshold may be 5 nm, 7 nm, or 10 nm.

In some Implementations, a plurality of semiconductor structures are included, and adjacently disposed semiconductor structures are spaced apart by a dielectric layer 2031. In an implementation, as shown in FIG. 8B, a first semiconductor structure 201 and a second semiconductor structure 202 that are adjacently disposed are spaced apart by the dielectric layer 2031.

In some implementations, a material of the dielectric layer 2031 includes, but is not limited to, silicon oxide.

In some Implementations, the first doped area 2018 extends a first preset size w1 from a side surface in contact with the dielectric layer 2031 along a direction in which the gate structure 2022 points to the semiconductor pillar 2010; and along the direction in which the gate structure 2022 points to the semiconductor pillar 2010, the largest doping concentration of the first doped area 2018 is located on a side surface of the first doped area 2018 in contact with the dielectric layer 2031.

In practical applications, the first preset size w1 is mainly related to a radial width of the semiconductor pillar 2010. When the radial width of the semiconductor pillar 2010 is larger, the first preset size w1 may also be set larger.

In some implementations, a range of a ratio of the radial width of the semiconductor pillar to the first preset size w1 is 1-10. In an implementation, the ratio of the radial width of the semiconductor pillar to the first preset size w1 may be 1, 5, or 10. When the ratio of the radial width of the semiconductor pillar to the first preset size w1 is 1, it indicates that a size of the first doped area in an X direction is equal to the radial width of the semiconductor pillar.

The above-mentioned range of the ratio of the radial width of the semiconductor pillar 2010 to the first preset size w1 is only for exemplary description, and is not used to limit the range of the ratio of the radial width of the semiconductor pillar 2010 to the first preset size w1 in the examples of the present disclosure.

In some implementations, a range of the first preset size w1 is 5 nm to 10 nm. Further, in an implementation, the first preset size w1 may be 5 nm, 7 nm, or 10 nm.

In some Implementations, the semiconductor structure further includes: a source and a drain, wherein the source and the drain are located at ends of the first portion and the second portion of the first doped area away from the gate structure along the first direction, respectively; and the smallest doping concentrations of the source and the drain are greater than the largest doping concentration of the first doped area.

In an implementation, the first semiconductor structure 201 includes a source 2017 and a drain 2025, wherein the source 2017 and the drain 2025 are located at ends of the first portion 2018-1 and the second portion 2018-2 of the first doped area 2018 away from the gate structure 2022 along the first direction, respectively; and the smallest doping concentrations of the source 2017 and the drain 2025 are greater than the largest doping concentration of the first doped area 2018.

In some Implementations, a doping concentration of the source 2017 decreases along a direction in which the first end points to the second end, and a doping concentration of the drain 2025 decreases along a direction in which the second end points to the first end.

In some Implementations, the semiconductor structure further includes: a channel area, wherein the channel area is a region other than the first doped area 2018 between the source 2017 and the drain 2025; and the smallest doping concentration of the first doped area 2018 is greater than the largest doping concentration of the channel area.

In some Implementations, a plurality of semiconductor structures are included, and adjacently disposed semiconductor structures are spaced apart by a dielectric layer; and a doped ion concentration of the dielectric layer is less than or equal to a second preset threshold. In an implementation, the first semiconductor structure 201 and the second semiconductor structure 202 that are adjacently disposed are spaced apart by the dielectric layer 2031. A doped ion concentration of the dielectric layer 2031 is less than or equal to the second preset threshold.

In some implementations, the second preset threshold is 0, and the doped ion concentration of the dielectric layer 2031 is equal to the second preset threshold, that is, the dielectric layer 2031 is undoped.

In some Implementations, the plurality of semiconductor structures include the first semiconductor structure 201 and the second semiconductor structure 202 that are adjacently disposed; at least one of the gate structure 2022 of the first semiconductor structure 201 and the gate structure 2022 of the second semiconductor structure 202 is located on one of two sides of a respective semiconductor pillar 2010 away from the dielectric layer 2031; and the plurality of semiconductor structures further include a third semiconductor structure 203, and the third semiconductor structure 203 is located on a side of the first semiconductor structure 201 away from the second semiconductor structure 202.

In some Implementations, the memory device further includes a word line isolation structure, and the gate structure 2022 of the third semiconductor structure 203 and the gate structure 2022 of the first semiconductor structure 201 are spaced apart by the word line isolation structure (not shown); and a size of the word line isolation structure along the first direction is greater than a size of the gate structure 2022 along the first direction.

A vertical size of the word line isolation structure in a Z direction here is greater than a vertical size of the gate structure 2022 in the Z direction, such that a better isolation effect is provided, and it may refer to the effect of the gate isolation 1062 in FIG. 2A.

In some Implementations, the plurality of semiconductor structures include the first semiconductor structure 201 and the second semiconductor structure 202 that are adjacently disposed; at least one of the gate structure 2022 of the first semiconductor structure 201 and the gate structure 2022 of the second semiconductor structure 202 is located on one of two sides of a respective semiconductor pillar 2010 away from the dielectric layer 2031; and at least one of the first semiconductor structure 201 and the second semiconductor structure 202 further includes: a second doped area 2030, wherein the second doped area 2030 extends a second preset size w2 from a side surface in contact with the dielectric layer 2031 toward the gate structure 2022, and a doping type of the second doped area 2030 is different from a doping type of at least one of the source 2017 and the drain 2025.

In practical applications, the second preset size w2 is mainly related to the radial width of the semiconductor pillar 2010. When the radial width of the semiconductor pillar 2010 is larger, the second preset size w2 may also be set larger.

In some implementations, the first preset size w1 and the second preset size w2 may be the same, or may be different.

In some implementations, a range of a ratio of the radial width of the semiconductor pillar 2010 to the second preset size w2 is 2-7. In an implementation, the ratio of the radial width of the semiconductor pillar to the second preset size w2 may be 2, 3, 4, 5, 6, or 7.

In some implementations, when the radial width of the semiconductor pillar is 10-20 nm, a range of the second preset size w2 is 1 nm to 10 nm. Further, in an implementation, the second preset size w2 may be 1 nm, 5 nm, or 10 nm.

In some Implementations, the smallest doping concentrations of the source 2017 and the drain 2025 are both greater than the largest doping concentration of the second doped area 2030.

In some Implementations, the doping types of the source 2017 and the drain 2025 is an N type, and the doping type of the second doped area 2030 is a P type.

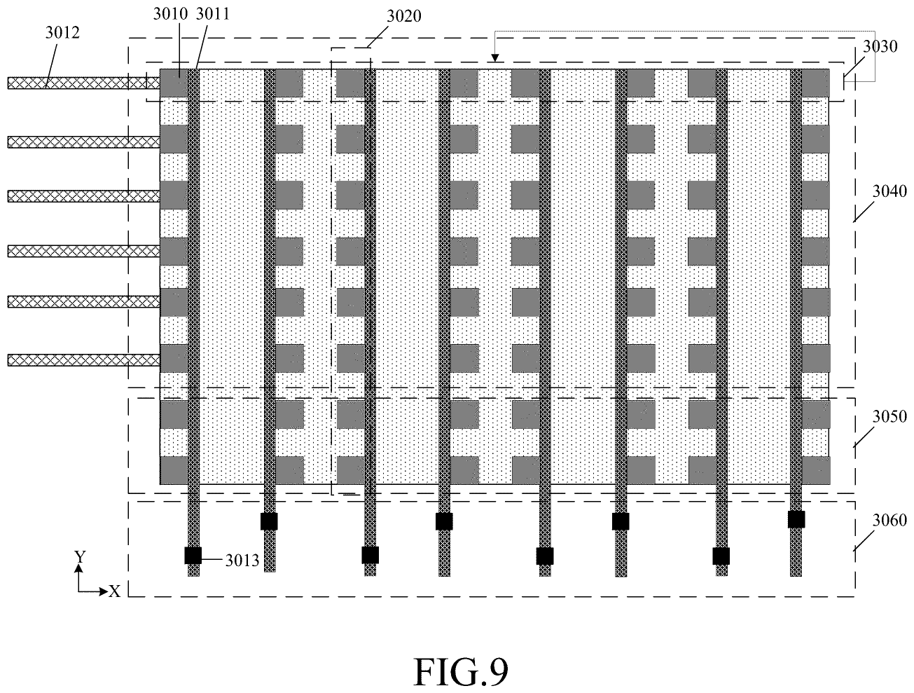

Implementations of the present disclosure further provide a memory device. As shown in FIG. 9, the memory device includes: a semiconductor pillar array including a plurality of rows of semiconductor pillars 3020 and a plurality of columns of semiconductor pillars 3030, with a semiconductor pillar 3010 extending along a first direction; a plurality of word lines 3011, with one of the word lines 3011 covers a part of a sidewall of one row of semiconductor pillars; a first doped area located at two opposite ends of a semiconductor pillar 3010 in a first region 3040 along the first direction, wherein the first region 3040 is a region where both the word line and the bit line 3012 passed through; and along a direction in which the word line 3011 points to the semiconductor pillar 3010, a doping concentration on a first side of the first doped area close to the word line 3011 is greater than a doping concentration on a second side of the first doped area away from the word line 3011; and a third doped area located at two opposite ends of a semiconductor pillar 3010 in a second region 3050 along the first direction, wherein the second region 3050 is located between the first region 3040 and a third region 3060, and the third region 3060 is configured for arranging word line contact structures 3013; and a doping concentration on a first side of the third region 3060 close to the word line 3011 is equal to a doping concentration on a second side of the third doped area away from the word line.

During the formation of the word line in the first region, a process of back-etching an initial gate (the third initial gate) on the back shown in FIG. 5H is performed. Therefore, conditions for forming the first doped area in the foregoing Implementations is provided. Here and below, for the semiconductor pillar, the first doped area, and the word line in the first region 3040, it may refer to the semiconductor pillar 2010, the first doped area 2018, and the gate structure 2022 shown in FIG. 8B for understanding.

During the formation of the word line in the second region, a process of back-etching the initial gate (the third initial gate) on the back shown in FIG. 5H does not need to be performed. Therefore, for the semiconductor pillar, the third doped area, and the word line in the second region 3050, it may refer to the semiconductor pillar 1030, a lightly doped drain 1064, and the gate structure 1036 shown in FIG. 2B for understanding.

In some Implementations, a spacing between an end surface of the word line close to the first doped area and an end surface of the first doped area close to the word line along the first direction is less than or equal to a first preset threshold; and a spacing between an end surface of the word line close to the third doped area and an end surface of the third doped area close to the word line in the first direction is greater than the first preset threshold. It can be understood that, the first doped area in the first region is aligned with the word line, and the third doped area in the second region is not aligned with the word line.

In an implementation, with reference to FIG. 8B, a spacing between an end surface of the word line (the gate structure 2022) close to the first doped area 2018 and an end surface of the first doped area 2018 close to the word line (the gate structure 2022) along the first direction is less than or equal to the first preset threshold. With reference to FIG. 2B, a spacing between an end surface of the word line (the gate structure 1036) close to the third doped area (the lightly doped drain 1064) and an end surface of the third doped area close to the word line (the gate structure 1036) in the first direction is greater than the first preset threshold.

In some Implementations, a range of the first preset threshold is 5 nm to 10 nm. The first preset threshold may be 5 nm, 7 nm, or 10 nm.

In some Implementations, a size of the first doped area along a preset direction is less than or equal to a size of the semiconductor pillar along the preset direction, wherein the preset direction is the same as an arrangement direction (an X direction) of semiconductor pillars in one column of semiconductor pillars; and a size of the third doped area along the preset direction (an X direction) is equal to the size of the semiconductor pillar along the preset direction.

In an implementation, that the size of the first doped area along the preset direction is less than or equal to the size of the semiconductor pillar along the preset direction may be understood as that the first preset size w1 in FIG. 8B is less than or equal to a radial width of the semiconductor pillar 2010.

That the size of the third doped area along the preset direction (an X direction) is equal to the size of the semiconductor pillar along the preset direction may be understood as that a size of the lightly doped drain 1064 in FIG. 2B in the X direction is equal to the radial width of the semiconductor pillar.

In some Implementations, the memory device further includes: a source and a drain, wherein at least one of the first doped area and the third doped area includes a first portion located at a first end of the semiconductor pillar and a second portion located at a second end of the semiconductor pillar, wherein the first end and the second end are two opposite ends of the semiconductor pillar along the first direction; and the source and the drain are located at ends of the first portion and the second portion of the first doped area/the third doped area away from the word line along the first direction, respectively; and the smallest doping concentrations of the source and the drain are greater than the largest doping concentration of the first doped area; and the smallest doping concentrations of the source and the drain are greater than the largest doping concentration of the third doped area.

Here, for the positions of the source and the drain in the memory device, it may refer to the positions of the source and the drain in FIG. 8B or FIG. 2B for understanding.

The doping concentrations of the first doped area and the third doped area are less than the doping concentration of the source/drain to improve a hot carrier injection effect.

It is to be understood that references to “an implementation” or “some Implementations” throughout this specification mean that particular features, structures, or characteristics related to the Implementations or implementation are included in at least one implementation of the present disclosure. Therefore, “in an implementation” or “in some Implementations” presented everywhere throughout this specification does not necessarily refer to the same implementation. In addition, these specific features, structures or characteristics may be combined in one or more Implementations in any suitable manner. It is to be understood that, in various Implementations of the present disclosure, the sequence number of each process does not mean the sequence of execution. The execution sequence of each process should be determined by its functions and internal logic, which should not constitute any limitation on the implementation process of the Implementations of the present disclosure. The serial numbers of the foregoing implementation of the present disclosure are merely for description, and do not represent the superiority or inferiority of the examples.

The above descriptions are merely specific implementations of the present disclosure, and the protection scope of the present disclosure is not limited thereto. Any variation or replacement that may be readily figured out by those skilled in the art within the technical scope disclosed by the present disclosure shall fall within the protection scope of the present disclosure.

What is claimed is:

1. A memory device, comprising:
a semiconductor structure, the semiconductor structure comprising:
a semiconductor pillar extending along a first direction;
a gate structure located on at least one side of the semiconductor pillar; and
a first doped area located at two opposite ends of the semiconductor pillar along the first direction, wherein along a direction in which the gate structure points to the semiconductor pillar, a doping concentration on a first side of the first doped area close to the gate structure is greater than a doping concentration on a second side of the first doped area away from the gate structure.

2. The memory device of claim 1, wherein a doping concentration of the first doped area decreases along the direction in which the gate structure points to the semiconductor pillar.

3. The memory device of claim 1, wherein the first doped area comprises a first portion located at a first end of the semiconductor pillar and a second portion located at a second end of the semiconductor pillar, and the first end and the second end are two opposite ends of the semiconductor pillar along the first direction; and a spacing between an end surface of the gate structure close to the first portion and an end surface of the first portion close to the gate structure along the first direction and a spacing between an end surface of the gate structure close to the second portion and an end surface of the second portion close to the gate structure are both less than or equal to a first preset threshold, and a range of the first preset threshold is 5 nm to 10 nm.

4. The memory device of claim 2, wherein the memory device comprises a plurality of semiconductor structures, and adjacently disposed semiconductor structures are spaced apart by a dielectric layer;
the first doped area extends a first preset size from a side surface in contact with the dielectric layer along the direction in which the gate structure points to the semiconductor pillar; and along the direction in which the gate structure points to the semiconductor pillar, the first doped area has the largest doping concentration on the side surface of the first doped area in contact with the dielectric layer.

5. The memory device of claim 3, wherein the semiconductor structure further comprises a source and a drain; the source and the drain are located at ends of the first portion and the second portion of the first doped area away from the gate structure along the first direction, respectively;
the smallest doping concentrations of the source and the drain are greater than the largest doping concentration of the first doped area;
a doping concentration of the source decreases along a direction in which the first end points to the second end; and
a doping concentration of the drain decreases along a direction in which the second end points to the first end.

6. The memory device of claim 5, wherein the semiconductor structure further comprises a channel area, which is a region other than the first doped area between the source and the drain; and the smallest doping concentration of the first doped area is greater than the largest doping concentration of the channel area.

7. The memory device of claim 1, wherein the memory device comprises a plurality of semiconductor structures, and adjacently disposed semiconductor structures are spaced apart by a dielectric layer; and a doped ion concentration of the dielectric layer is less than or equal to a second preset threshold.

8. The memory device of claim 7, wherein the plurality of semiconductor structures comprise a first semiconductor structure and a second semiconductor structure that are adjacently disposed;
at least one of the gate structure of the first semiconductor structure and the gate structure of the second semiconductor structure is located on one of two sides of a respective semiconductor pillar away from the dielectric layer; and
the plurality of semiconductor structures further comprise a third semiconductor structure, which is located on a side of the first semiconductor structure away from the second semiconductor structure; and
the memory device further comprises a word line isolation structure, and the gate structure of the third semiconductor structure and the gate structure of the first semiconductor structure are spaced apart by the word line isolation structure; and a size of the word line isolation structure along the first direction is greater than a size of the gate structure along the first direction.

9. The memory device of claim 7, wherein the plurality of semiconductor structures comprise a first semiconductor structure and a second semiconductor structure that are adjacently disposed;
at least one of the gate structure of the first semiconductor structure and the gate structure of the second semiconductor structure is located on one of two sides of a respective semiconductor pillar away from the dielectric layer; and at least one of the first semiconductor structure and the second semiconductor structure further comprises:
a second doped area, wherein the second doped area extends a second preset size from a side surface in contact with the dielectric layer toward the gate structure, and a doping type of the second doped area is different from a doping type of at least one of a source and a drain.

10. The memory device of claim 9, wherein the smallest doping concentrations of the source and the drain are both greater than the largest doping concentration of the second doped area.

11. A memory device, comprising:
a semiconductor pillar array comprising a plurality of rows of semiconductor pillars and a plurality of columns of semiconductor pillars, wherein the semiconductor pillar extends along a first direction;
a plurality of word lines, wherein one of the word lines covers a part of a sidewall of one row of semiconductor pillars;
a first doped area located at two opposite ends of the semiconductor pillar in a first region along the first direction, wherein the first region is a region where both a word line and a bit line extend through; and along a direction in which the word line points to the semiconductor pillar, a doping concentration on a first side of the first doped area close to the word line is greater than a doping concentration on a second side of the first doped area away from the word line; and
a third doped area located at two opposite ends of the semiconductor pillar in a second region along the first direction, wherein the second region is located between the first region and a third region, and the third region is configured for arranging a word line contact structure; and a doping concentration on a first side of the third doped area close to the word line is equal to a doping concentration on a second side of the third doped area away from the word line.

12. The memory device of claim 11, wherein
a spacing between an end surface of the word line close to the first doped area and an end surface of the first doped area close to the word line along the first direction is less than or equal to a first preset threshold;
a spacing between an end surface of the word line close to the third doped area and an end surface of the third doped area close to the word line in the first direction is greater than the first preset threshold; and
a range of the first preset threshold is 5 nm to 10 nm.

13. The memory device of claim 11, wherein
a size of the first doped area along a preset direction is less than or equal to a size of the semiconductor pillar along the preset direction, wherein the preset direction is the same as an arrangement direction of semiconductor pillars in one column of semiconductor pillars; and
a size of the third doped area along the preset direction is equal to the size of the semiconductor pillar along the preset direction.

14. The memory device of claim 11, further comprises a source and a drain, wherein
at least one of the first doped area and the third doped area comprises a first portion located at a first end of the semiconductor pillar and a second portion located at a second end of the semiconductor pillar, wherein the first end and the second end are two opposite ends of the semiconductor pillar along the first direction; and the source and the drain are located at ends of the first portion and the second portion of the at least one of the first doped area or the third doped area away from the word line along the first direction, respectively; and
the smallest doping concentrations of the source and the drain are greater than the largest doping concentration of the first doped area; and the smallest doping concentrations of the source and the drain are greater than the largest doping concentration of the third doped area.

15. A manufacturing method of a memory device, comprising:
providing a semiconductor layer;
forming a semiconductor structure in the semiconductor layer, wherein the semiconductor structure comprises a semiconductor pillar, a gate structure, and a first doped area, and forming the semiconductor structure comprises:
forming the semiconductor pillar extending along a first direction;
forming the gate structure on at least one side of the semiconductor pillar; and
forming the first doped areas at two opposite ends of the semiconductor pillar along the first direction, wherein along a direction in which the gate structure points to the semiconductor pillar, a doping concentration on a first side of the first doped area close to the gate structure is greater than a doping concentration on a second side of the first doped area away from the gate structure.

16. The manufacturing method of claim 15, wherein forming the gate structure and the first doped area comprises:
forming a first initial gate covering at least one side of the semiconductor pillar;
removing a part of the first initial gate along the first direction from a first surface and a second surface of the semiconductor layer, respectively, to form the gate structure and expose a part of the semiconductor pillar, wherein the first surface and the second surface are two opposite surfaces of the semiconductor layer along the first direction; and
forming the first doped areas from surfaces of exposed parts of the semiconductor pillar, respectively, in a region extending a first preset size along a direction perpendicular to the first direction.

17. The manufacturing method of claim 15, wherein forming the gate structure and the first doped area comprises:
forming a sacrificial layer at a bottom of at least one side of the semiconductor pillar;
forming a second initial gate covering a respective side of the semiconductor pillar on the sacrificial layer;
removing top portions of the second initial gate and the sacrificial layer, to form the gate structure and expose a top and a bottom of a respective side surface of the semiconductor pillar; and
forming the first doped areas from surfaces of exposed parts of the semiconductor pillar, respectively, in a region extending a first preset size along a direction perpendicular to the first direction.

18. The manufacturing method of claim 16, wherein forming the first doped area comprises:
forming first portions and second portions of the first doped areas from surfaces of exposed parts of the semiconductor pillar, respectively, in a region extending the first preset size along a direction perpendicular to the first direction by a molecular layer deposition process or a rapid vapor deposition process.

19. The manufacturing method of claim 18, forming a first portion and a second portion of the first doped area comprises:
removing a part of the first initial gate from the first surface of the semiconductor layer along the first direction to form a third initial gate, so as to expose a part of the semiconductor pillar;
forming a first initial portion of the first doped area from a surface of the exposed part of the semiconductor pillar in a region extending the first preset size along a direction perpendicular to the first direction;
doping a part of the first initial portion away from the third initial gate from the first surface of the semiconductor layer along the first direction by an ion implantation process, wherein the doped portion forms a source, and the remaining first initial portion that is not doped by an ion implantation process forms the first portion of the first doped area;
after forming the source and the first portion, removing a part of the third initial gate from the second surface of the semiconductor layer along the first direction to form the gate structure, so as to expose a part of the semiconductor pillar;
forming a second initial portion of the first doped area from a surface of the exposed part of the semiconductor pillar in a region extending the first preset size along a direction perpendicular to the first direction; and
doping a partial region of the second initial portion away from the gate structure from the second surface of the semiconductor layer along the first direction by an ion implantation process, wherein the doped partial region forms a drain, and the remaining second initial portion that is not doped by an ion implantation process forms the second portion of the first doped area.

20. The manufacturing method of claim 18, wherein forming a first portion and a second portion of the first doped area comprises:
forming a drain at the bottom of at least one side of the semiconductor pillar by a diffusion process;
forming first initial portions and the second portions of the first doped areas from surfaces of exposed parts of the semiconductor pillar at a top and a bottom of a respective side surface, respectively, in a region extending the first preset size along a direction perpendicular to the first direction; and
doping a partial region of the first initial portion away from the gate structure from a top of the semiconductor layer along the first direction by an ion implantation process, wherein the doped partial region forms a source, and the remaining first initial portion that is not doped by an ion implantation process forms the first portion of the first doped area.
